(19) United States
(12) Patent Application Publication
(10) Pub. No.: US 2009/0039335 A1
(43) Pub. Date: Feb. 12, 2009

(54) SEMICONDUCTOR DEVICE AND MANUFACTURING METHOD OF THE SAME

(76) Inventors: Motoyasu Terao, Hinode (JP); Kenzo Kurotsuchi, Kodaira (JP); Riichiro Takemura, Los Angeles, CA (US); Norikatsu Takaura, Tokyo (JP); Satoru Hanzawa, Hachioji (JP)

Correspondence Address: MILES & STOCKBRIDGE PC, 1751 PINNACLE DRIVE, SUITE 500, MCLEAN, VA, 22102-3833, US

(21) Appl. No.: 12/162,769

(22) PCT Filed: Feb. 9, 2006
(86) PCT No.: PCT/JP2006/302240

§ 371 Date: Oct. 16, 2008

(51) Int. Cl. H01L 45/00

(52) U.S. Cl. 257/4; 257/E45.002

(57) ABSTRACT

On an insulating film (31) in which a plug (35) is embedded, a second component releasing region (45) made of a first component and a second component, a solid electrolyte region (46) made of chalcogenide and an upper electrode region (47) are sequentially formed. The second component releasing region (45) made of a first component and a second component is composed of dome-shaped electrode portions (43) and an insulating film (44) burying the peripheries of the electrode portions (43), and at least one electrode portion (43) exists on the plug (34). The electrode portion (43) is composed of a first portion made of the first component such as tantalum oxide that is stable even when electric field is applied thereto and a second portion made of the second component such as copper or silver that is easily diffused in the solid electrolyte region (42) and moves therein by the application of an electric field. The second component supplied from the electrode portion (43) moves in the solid electrolyte region (46), thereby storing the information.

### TECHNICAL FIELD

The present invention relates to a semiconductor device and a manufacturing method of the same. More particularly, it relates to a semiconductor device having a nonvolatile storage element and a manufacturing method of the same.

### BACKGROUND ART

A nonvolatile memory called a polarized memory or a solid electrolyte memory has been known (for example, Non-Patent Document 1 and Non-Patent Document 2). In this memory, information is written by means of the change in resistance in a storage element in accordance with the direction of voltage applied to the storage element. Since a resistance value is used as a signal in this memory, a read signal is large and a sensing operation is easy. The configuration of a storage device is the same as that of a phase change memory except for the polarity of rewriting voltage.

The phase change memory is disclosed in, for example, U.S. Pat. No. 5,883,827 (Patent Document 1).

According to the configuration of the phase change memory of FIG. 12 of U.S. Pat. No. 5,883,827, the phase change memory includes a memory array, a row decoder XDEC, a bit (column) decoder YDEC, a read circuit RC, and a write circuit WC. The memory array is configured by disposing a memory cell MC at each intersection of word lines WLp (p=1, . . . , n) and data lines DLr (r=1, . . . , m). In each memory cell, a storage element R and a selection transistor QM connected in series are inserted between a bit line DL and ground potential. The word line WL is connected to the gate of the selection transistor, and the bit selection line YSr (r=1, . . . , m) is connected to a corresponding bit selection switch QAr, respectively.

In this configuration, when the selection transistor on the word line selected by the row decoder XDEC becomes conductive and the bit selection switch corresponding to the bit selection line selected by the bit decoder YDEC becomes conductive, a current path is formed in a selected memory cell, and a read signal is generated in a common bit line I/O. Since the resistance value of the selected memory cell is different depending on stored information, the voltage outputted to the common bit line I/O differs depending on the stored information. By distinguishing the difference with the read circuit RC, the stored information in the selected memory cells is read.

Patent Document 1: U.S. Pat. No. 5,883,827

Non-Patent Document 1: “IEEE International Solid-State Circuits Conference (ISSCC)2004”, Digest, (U.S.A), 2004, P.16.3, T. Sakamoto, S. Kaeriyama, H. Sunamura, M. Mizuno, H. Kawaura, T. Hasegawa, K. Terabe, T. Nakayama and M. Aono Non-Patent Document 2: Proc. Non-Volatile Memory Technology Symposium (NVMTS) 2004, (U.S.A), 2004, P. 10-17, M. N. Kozicki, C. Gopalan, M. Balakrishnan, M. Park and M. Mitkova.

### DISCLOSURE OF THE INVENTION

### Problem to be Solved by the Invention

Examinations by the inventors of the present invention have revealed the followings.

In a metal-chalcogenide solid electrolyte memory in which metal is used for an electrode and chalcogenide is used for solid electrolyte and the solid electrolyte is disposed between the electrodes, the ion movement is the memory mechanism and a low-resistance conducting path with a high concentration of positive ions such as Ag and Cu is formed in a chalcogenide layer or an oxide layer. By controlling the voltage between the electrodes, the conducting path of the metal ions diffused in the solid electrolyte from the metal electrodes can be controlled, thereby changing the resistance value, and a function as a non-volatile memory is achieved. However, by repeatedly rewriting the memory, the metal ions are diffused in the solid electrolyte from the metal electrodes and the shape of the electrode is changed. As a result, the rewriting characteristics become unstable, and there is the possibility that a different resistance is given in every rewrite operation. Moreover, if the memory is repeatedly rewritten, the concentration of Ag, Cu and others in the solid electrolyte is extremely increased due to the diffusion from the electrodes, and there is the possibility that the resistance becomes unchanged at an intermediate resistance between ON and OFF. The problems above will decrease the performance of a semiconductor device that can store information.

An object of the present invention is to provide a technology capable of improving the performance of a semiconductor device that can store information.

The above and other objects and novel characteristics of the present invention will be apparent from the description of this specification and the accompanying drawings.

### Means for Solving the Problems

The typical ones of the inventions disclosed in this application will be briefly described as follows.

A semiconductor device according to the present invention comprises: a second component releasing cell made of a first component and a second component; and a solid electrolyte region adjacent to the second component releasing cell, wherein the second component supplied from the second component releasing cell moves inside the solid electrolyte region to change physical characteristics, thereby storing information.

Also, a manufacturing method of a semiconductor device according to the present invention is a manufacturing method of a semiconductor device comprising: a second component releasing cell; and a solid electrolyte region adjacent to the second component releasing cell, wherein an element supplied from the second component releasing cell moves inside the solid electrolyte region, thereby storing information, and the method comprises the steps of: (a) preparing a semiconductor substrate; (b) forming a first material film for forming the second component releasing cell on the semiconductor substrate; (c) dividing the first material film into a plurality of portions, at least one of the portions being the second component releasing cell; (d) after the step (c), forming a first insulating film so as to cover the second component releasing cell on the semiconductor substrate; (e) removing the first insulating film on the second component releasing cell, thereby leaving the first insulating film around the second component releasing cell; and (f) after the step (e), forming the solid electrolyte region adjacent to the second component releasing cell and the first insulating film.

The above-mentioned change of physical characteristics means, for example, the change of an electric resistance, the change of an electric capacity and the like between the electrodes between which the configuration is disposed. The change of an electric resistance is preferable.

### EFFECT OF THE INVENTION

The effects obtained by typical aspects of the present invention will be briefly described below.

The present invention can improve the performance of a semiconductor device that can store information.

### BRIEF DESCRIPTION OF THE DRAWINGS

FIG. 1 is a circuit diagram showing an example of a memory array structure of a memory region in a semiconductor device according to an embodiment of the present invention;

FIG. 2 is a plan view showing a planar layout corresponding to the array structure of FIG. 1;

FIG. 3 is a sectional view showing the principal part of the semiconductor device according to an embodiment of the present invention;

FIG. 4 is a sectional view showing the principal part of the region in the vicinity of a resistor element of the semiconductor device of FIG. 3;

FIG. 5 is a sectional view showing the principal part of the resistor element of FIG. 4;

FIG. 6 is a table showing the relation between the state of the solid electrolyte region and the resistance value of the resistor element;

FIG. 7 is a sectional view showing the principal part of the region in the vicinity of a resistor element of the semiconductor device according to another embodiment of the present invention;

FIG. 8 is an explanatory diagram showing the timing of read operation of the memory array;

FIG. 9 is an explanatory diagram showing the timing of write operation of the memory array;

FIG. 10 is a sectional view showing the principal part of the semiconductor device during a manufacturing process according to an embodiment of the present invention;

FIG. 11 is a sectional view showing the principal part of the semiconductor device during the manufacturing process continued from FIG. 10;

FIG. 12 is a sectional view showing the principal part of the semiconductor device during the manufacturing process continued from FIG. 11;

FIG. 13 is a sectional view showing the principal part of the semiconductor device during the manufacturing process continued from FIG. 12;

FIG. 14 is a sectional view showing the principal part of the semiconductor device during the manufacturing process continued from FIG. 13;

FIG. 15 is a sectional view showing the principal part of the semiconductor device during the manufacturing process continued from FIG. 14;

FIG. 16 is a sectional view showing the principal part of the semiconductor device during the manufacturing process continued from FIG. 15;

FIG. 17 is a sectional view showing the principal part of the semiconductor device during the manufacturing process continued from FIG. 16;

FIG. 18 is a sectional view showing the principal part of the semiconductor device during the manufacturing process continued from FIG. 17;

FIG. 19 is a sectional view showing the principal part of a second component releasing layer made of a first component and a second component during a forming process;

FIG. 20 is a sectional view showing the principal part of the second component releasing layer made of a first component and a second component during the forming process continued from FIG. 19;

FIG. 21 is a sectional view showing the principal part of the second component releasing layer made of a first component and a second component during the forming process continued from FIG. 20;

FIG. 22 is a sectional view showing the principal part of the second component releasing layer made of a first component and a second component during the forming process continued from FIG. 21;

FIG. 23 is a sectional view showing the principal part of the second component releasing layer made of a first component and a second component during the forming process continued from FIG. 22;

FIG. 24 is a sectional view showing the principal part of the second component releasing layer made of a first component and a second component during the forming process continued from FIG. 23;

FIG. 25 is a sectional view showing the principal part of the second component releasing layer made of a first component and a second component during the forming process continued from FIG. 24;

FIG. 26 is a sectional view showing the principal part of a semiconductor device according to another embodiment of the present invention;

FIG. 27 is a sectional view showing the principal part of the semiconductor device during a manufacturing process according to another embodiment of the present invention;

FIG. 28 is a sectional view showing the principal part of the semiconductor device during the manufacturing process continued from FIG. 27;

FIG. 29 is a sectional view showing the principal part of the semiconductor device during the manufacturing process continued from FIG. 28;

FIG. 30 is a sectional view showing the principal part of the semiconductor device during the manufacturing process continued from FIG. 29;

FIG. 31 is a sectional view showing the principal part of the semiconductor device during the manufacturing process continued from FIG. 30;

FIG. 32 is a sectional view showing the principal part of the semiconductor device during the manufacturing process continued from FIG. 31;

FIG. 33 is a sectional view showing the principal part of a semiconductor device according to another embodiment of the present invention;

FIG. 34 is a sectional view showing the principal part of the semiconductor device during a manufacturing process according to another embodiment of the present invention;

FIG. 35 is a sectional view showing the principal part of the semiconductor device during the manufacturing process continued from FIG. 34;

FIG. 36 is a sectional view showing the principal part of the semiconductor device during the manufacturing process continued from FIG. 35;

FIG. 37 is a sectional view showing the principal part of the semiconductor device during the manufacturing process continued from FIG. 36; and

FIG. 38 is a sectional view showing the principal part of the semiconductor device during the manufacturing process continued from FIG. 37.

### BEST MODE FOR CARRYING OUT THE INVENTION

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof. Also, in the embodiments described below, when referring to the number of elements (including number of pieces, values, amount, range, and the like), the number of the elements is not limited to a specific number unless otherwise stated or except the case where the number is apparently limited to a specific number in principle, and the number larger or smaller than the specified number is also applicable. Further, in the embodiments described below, it goes without saying that the components (including element steps) are not always indispensable unless otherwise stated or except the case where the components are apparently indispensable in principle. Similarly, in the embodiments described below, when the shape of the components, positional relation thereof, and the like are mentioned, the substantially approximate and similar shapes and the like are included therein unless otherwise stated or except the case where it can be conceived that they are apparently excluded in principle. The same goes for the numerical value and the range described above.

Hereinafter, embodiments of the present invention will be described in detail with reference to the accompanying drawings. Note that components having the same function are denoted by the same reference numbers throughout the drawings for describing the embodiments, and the repetitive description thereof will be omitted. In addition, the description of the same or similar portions is not repeated in principle unless particularly required in the following embodiments.

Also, in the drawings used in the embodiments, hatching is used in some cases even in a plan view so as to make the drawings easy to see.

### FIRST EMBODIMENT

A semiconductor device and a manufacturing method of the same will be described with reference to the accompanying drawings.

The semiconductor device of the present embodiment is a semiconductor device having a nonvolatile memory (nonvolatile storage element), and it includes a memory region in which a memory cell array of the nonvolatile memory is formed.

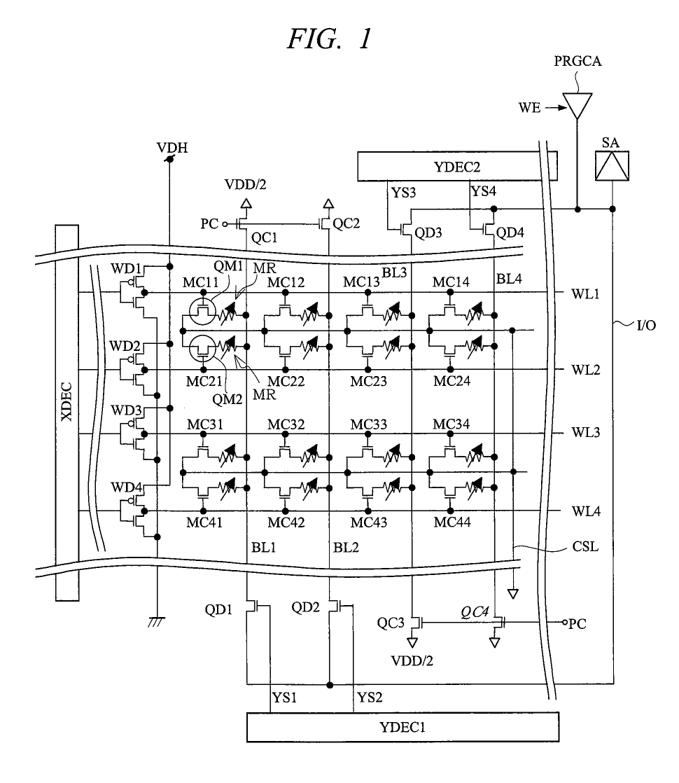

An example of a structure of the memory array of this memory region will be described with reference to a circuit diagram of FIG. 1.

The memory array structure shown in FIG. 1 is known as a NOR type, and it is suitable for storing system programs because read operation can be performed at high speed, and is typically used for a single memory chip or for a memory mounted together with a logic LSI such as a microcomputer. Moreover, the memory cells are connected to a common source line CSL and the common source line CSL is characterized by being fixed to the intermediate voltage of a power supply voltage VDD and a ground voltage VSS. In FIG. 1, in order to prevent the drawing from being complicated, only a part of the array including 4 word lines of WL1 to WL4 and 4 bit lines of BL1 to BL4 is shown. MC11 to MC14 denote 4 memory cells connected to WL1. Similarly, MC21 to MC24, MC31 to MC34 and MC41 to MC44 denote memory cells connected to WL2 to WL4, respectively. BL1 is a bit line to which the memory cells MC11 to MC41 are connected. Similarly, the memory cells MC12 to MC42, MC13 to MC43 and MC14 to MC44 are connected to the bit lines BL2, BL3 and BL4, respectively.

In the configuration of each memory cell, one MISFET (corresponding to one of MISFETs QM1 and QM2 described later) and a storage element (memory material) MR (corresponding to a solid electrolyte region 46 or a resistor element 48 including the solid electrolyte region 46 described later) connected thereto in series are inserted between the bit lines BL1 to BL4 and the common source line CSL. The common source line CSL is fixed to the intermediate voltage (for example, VDD/2 in FIG. 1) of the power supply voltage VDD and the ground voltage VSS. Each word line (WL1 to WL4) is connected to a gate electrode of the MISFET constituting each memory cell. Each bit line (BL1 to BL4) is connected to the storage element (memory material) MR constituting each memory cell. The word lines WL1 to WL4 are driven by word drivers WD1 to WD4, respectively. Signals from an X address decoder (row decoder) XDEC determine which one of the word drivers WD1 to WD4 will be selected.

Each of the word drivers WD1 to WD4 has the same circuit configuration as a publicly known inverter circuit composed of one p channel type MISFET (hereinafter, referred to as a pMISFET) and one n channel MISFET (hereinafter, referred to as an nMISFET). A boost voltage VDH (for example, voltage higher than the power supply voltage VDD at least by the threshold voltage of the nMISFET though details thereof will be described later) is supplied to the source of the pMISFET constituting each of the word drivers WD1 to WD4, and the source of the nMISFET is grounded. QC1 is an nMISFET for driving the bit line BL1 to the same voltage (VDD/2 here) as the common source line CSL, and is controlled by a precharge enable signal PC. Similarly, QC2 to QC4 are nMISFETs for precharging the bit lines BL2 to BL4. QD1 is an nMISFET for connecting the bit line BL1 to a sense amplifier SA or a rewriting circuit PRGCA. Similarly, QD2 to QD4 are nMISFETs for connecting the bit lines BL2 to BL4 to the sense amplifier SA or the rewriting circuit PRGCA, respectively. Each transistor (QD1 to QD4) is selected via a bit decoder YDEC1 or a bit decoder YDEC2 in accordance with an address input. In this example, the bit decoder YDEC1 and the bit decoder YDEC2 alternately handle the bit lines to be selected every two bit lines. An output caused by a read operation is detected by the sense amplifier SA. Also, write data is inputted by the rewriting circuit PRGCA. Note that, in consideration of the withstand voltage, the transistors QC1 to QC4 and QD1 to QD4, to the gate electrodes of which the boost voltage VDH is applied, and the selection transistors in the memory cells MC11 to MC44 have gate oxide films formed relatively thicker than those of the peripheral transistors.

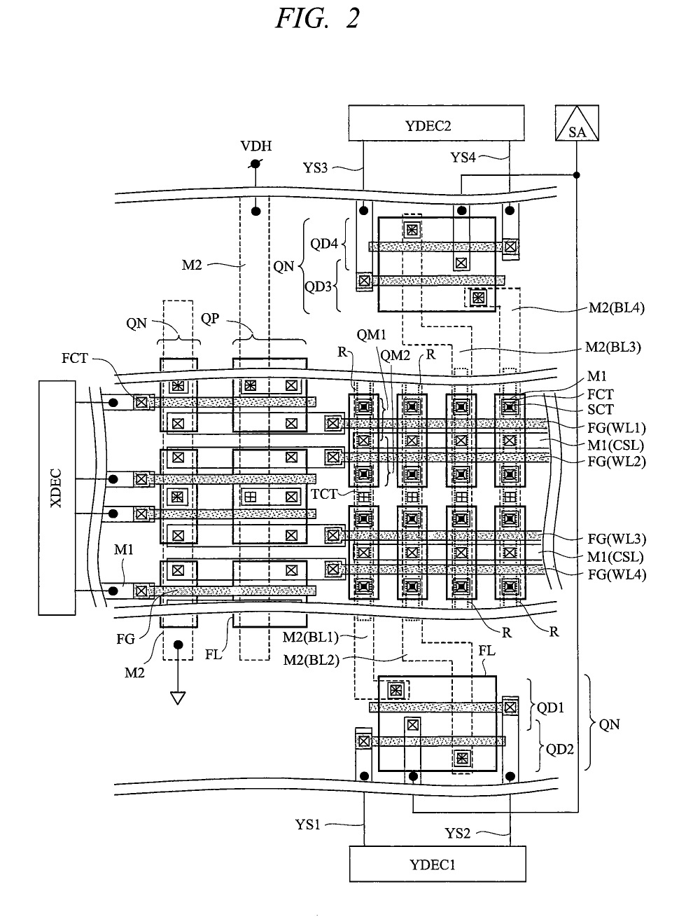

FIG. 2 shows a planar layout (plan view) corresponding to the array configuration of FIG. 1.

In FIG. 2, FL is an active region, M1 is a first metal layer (corresponding to a wiring 27 described later), M2 is a second metal layer (corresponding to a wiring 62 described later), a gate electrode pattern FG is a layer (corresponding to a conductor film pattern constituting gate electrodes 6a, 6b and 6C and others described later) used as a gate electrode of a transistor formed on a silicon substrate, FCT is a contact hole (corresponding to a contact hole 22 described later) connecting an upper surface of FL and a lower surface of M1, R (corresponding to a resistor element 48 described later) is a laminated film of a storage element (corresponding to a solid electrolyte region 46 described later) and an upper electrode layer thereof (corresponding to upper electrode layer 47 described later), SCT is a contact hole (corresponding to a through hole 34 described later) connecting an upper surface of M1 and a lower surface of R, and TCT is a contact hole (corresponding to a through hole 55 described later) connecting the upper surface of M1 and a lower surface of M2.

R is extended up to M2 via TCT between the memory cells connected to the same bit line. This M2 is used as a bit line for each. The word lines WL1 to WL4 are formed of FG. A lamination of polysilicon and silicide (alloy of silicon and high melting point metal) or the like is used for FG. An MISFET constituting the memory cell MC11 is QM1. MISFET QM2 constituting MC21 shares the source region with QM1. As shown in FIG. 2, MISFETs constituting other cells also follow this configuration. The bit lines BL1 to BL4 are connected to the source side of the transistors (MISFET) QD1 to QD4 disposed on the outer circumference of the memory array. QD1 and QD2 share the same drain region, and QD3 and QD4 share the same drain region. These transistors have a function to precharge each bit line. In addition, these transistors also have a function to select a specified bit line in response to the signal from YDEC1 or YDEC2. FIG. 2 shows an example of an n channel type. Though not particularly limited, the circuit elements constituting each block are typically formed on one semiconductor substrate such as a single crystal silicon by a technology for a semiconductor integrated circuit such as CMISFET (Complementary MISFET: complementary MIS transistor). Further, a chalcogenide material or the like is used in combination with the technology to form integrated circuits. Publicly known photolithography and dry etching can be used for the patterning of these patterns. These manufacturing processes will be described in more detail later.

FIG. 2 also shows an example of the layout in which R (storage element) is patterned in the bit line direction. However, the layout is not limited thereto, but various layouts are possible. For example, since the electrodes facing to the bit lines when seen from the storage element of R (corresponding to the solid electrolyte region 46 described later) are fixed to VDD/2, a single board form like in a dynamic random access memory can also be adopted. In this case, since a patterning process can be simplified, the manufacturing cost can be reduced.

Next, the structure of the semiconductor device according to the present embodiment will be described in more detail.

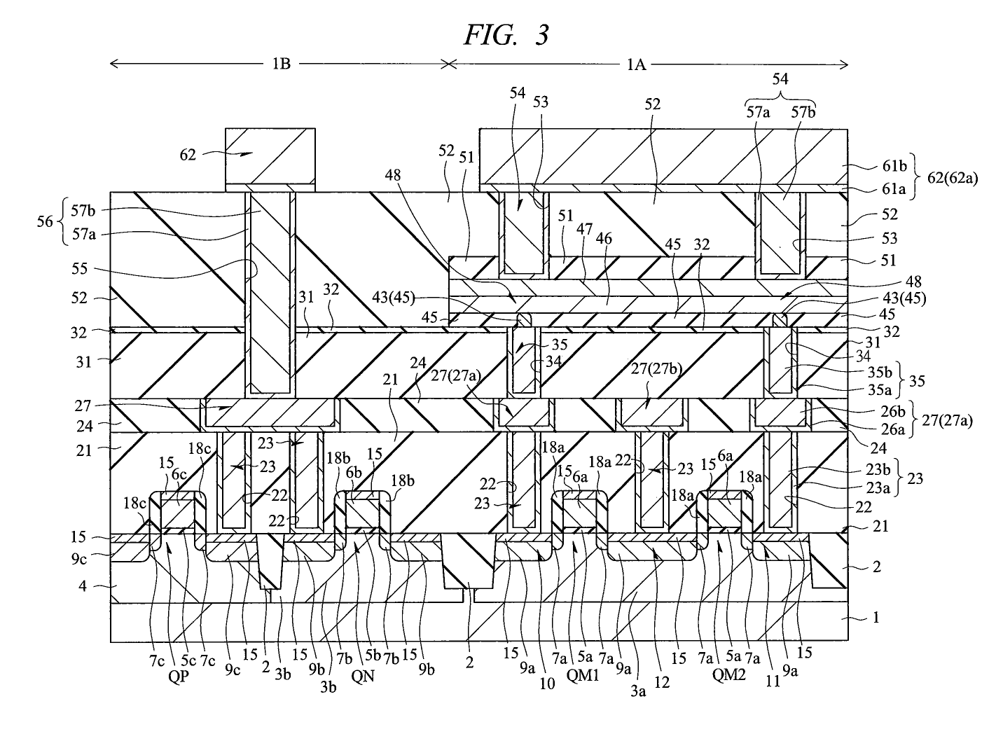

FIG. 3 is a sectional view showing a principal part of the semiconductor device according to the present embodiment. In FIG. 3, the section (section of the principal part) of a memory region 1A and the section (section of the principal part) of a peripheral circuit region (logical circuit region) 1B are illustrated. The memory region 1A corresponds to a part of the region in which the memory cell of the nonvolatile memory (nonvolatile storage element) according to the present embodiment is formed. The peripheral circuit region 1B corresponds to a part of the peripheral circuit region (region in which an n channel MISFET and a p channel MISFET are formed) of the semiconductor device, and an X decoder circuit, a Y decoder circuit, a sense amplifier circuit (sense amplifier circuit of a memory cell), an input/output circuit, a logic circuit (logic circuit for CPU or MPU) and others are formed by the MISFETs for constituting peripheral circuits (MISFETs formed in the peripheral circuit region 1B). In FIG. 3, the section of the memory region 1A and the peripheral circuit region 1B are adjacently illustrated for the sake of easy understanding, but the positional relationship of the section of the memory region 1A and the peripheral circuit region 1B can be changed as necessary.

As shown in FIG. 3, isolation regions 2 made of an insulator are formed in the main surface of a semiconductor substrate (semiconductor wafer) 1 made of p type single crystal silicon, and p wells 3a and 3b and an n well 4 are formed in the active regions separated by the isolation regions 2. The p well 3a is formed in the memory region 1A, and the p well 3b and the n well 4 are formed in the peripheral circuit region 1B.

The n channel MISFETs (Metal Insulator Semiconductor Field Effect Transistor) QM1 and QM2 are formed on the p well 3a in the memory region 1A. An n channel MISFET (Metal Insulator Semiconductor Field Effect Transistor) QN is formed on the p well 3b in the peripheral circuit region 1B, and a p channel MISFET (Metal Insulator Semiconductor Field Effect Transistor) QP is formed on the n well 4 in the peripheral circuit region 1B.

The MISFETs QM1 and QM2 in the memory region 1A are MISFETs (transistor) for selecting memory cells in the memory region 1A. The MISFETs QM1 and QM2 are formed separately from each other on the p well 3a, and each of the MISFETs QM1 and QM2 has a gate insulating film 5a on the surface of the p well 3a and a gate electrode 6a adjacent to the gate insulating film 5a. A sidewall (sidewall insulating film, sidewall spacer) 8a formed of a silicon oxide film, a silicon nitride film or a laminated film thereof is formed on the sidewall of the gate electrode 6a.

In the p well 3a, a semiconductor region (an n type semiconductor region, an n type impurity diffusion layer) 10 serving as a drain region of the MISFET QM1, a semiconductor region (an n type semiconductor region, an n type impurity diffusion layer) 11 serving as a drain region of the MISFET QM2, and a semiconductor region (an n type semiconductor region, an n type impurity diffusion layer) 12 serving as a source region of the MISFETs QM1 and QM2 are formed. Each of the semiconductor regions 10, 11 and 12 has an LDD (Lightly Doped Drain) structure, and formed of an n⁻ type semiconductor region 7a and an n⁺ type semiconductor region 9a having an impurity concentration higher than that of the n⁻ type semiconductor region 7a. The n⁻ type semiconductor region 7a is formed in the p well 3a under the sidewall 8a, and the n⁺ type semiconductor region 9a is formed outside the gate electrode 6a and the sidewall 8a in the p well 3a, in which the n⁺ type semiconductor region 9a is formed in the p well 3a apart from the channel region by the width of the n type semiconductor region 7a. The semiconductor region 12 is shared by the adjacent MISFETs QM1 and QM2 formed in the same element active region to make a common source region. In the present embodiment, the case where the MISFETs QM1 and QM2 share the source region is described. However, it is also possible to share a drain region as another embodiment, and in such a case, the semiconductor region 12 will be a drain region and the semiconductor regions 10 and 11 will be source regions.

The MISFET QN formed in the peripheral circuit region 1B also has almost the same configuration as those of the MISFETs QM1 and QM2. More specifically, the MISFET QN has a gate insulating film 5b on the surface of the p well 3b and a gate electrode 6b adjacent to the gate insulating film 5b, and a sidewall (sidewall insulating film, sidewall spacer) 8b made of silicon oxide or the like is formed on the sidewall of the gate electrode 6b. An n⁻ type semiconductor region 7b is formed in the p well 3b under the sidewall 8b, and an n⁺ type semiconductor region 9b having an impurity concentration higher than that of the n⁻ type semiconductor region 7b is formed outside the n⁻ type semiconductor region 7b. The n-type semiconductor region 7b and the n⁺ type semiconductor region 9b form the source/drain region having a LDD structure for the MISFET QN.

The MISFET QP formed in the peripheral circuit region 1B has a gate insulating film 5c on the surface of the n well 4 and a gate electrode 6c adjacent to the gate insulating film 5c, and a sidewall (sidewall insulating film, sidewall spacer) 18c made of silicon oxide or the like is formed on the sidewall of the gate electrode 6c. A p⁻ type semiconductor region 7c is formed in the n well 4 under a sidewall 8C, and a p⁺ type semiconductor region 9c having an impurity concentration higher than that of the p⁻ type semiconductor region 7c is formed outside the p⁻ type semiconductor region 7c. The p⁻ type semiconductor region 7c and the p⁺ type semiconductor region 9c form the source/drain region having an LDD structure for the MISFET QP.

A metal silicide layer (for example, cobalt silicide (CoSi₂) layer) 15 is formed on each surface of the gate electrodes 6a, 6b and 6c, the n⁺ type semiconductor regions 9a and 9b, and the p⁺ type semiconductor region 9c. By the metal silicide layer 15, the diffusion resistance and the contact resistance of the n⁺ type semiconductor regions 9a and 9b and the p⁺ type semiconductor region 9c can be lowered.

An insulating film (interlayer insulation film) 21 is formed over a semiconductor substrate 1 so as to cover the gate electrodes 6a, 6b and 6c. The insulating film 21 is formed of, for example, a silicon oxide film or a laminated film of a silicon nitride film and a silicon oxide film adjacent thereto, and the upper surface of the insulating film 21 is evenly formed so that the memory region 1A and the peripheral circuit region 1B have almost the same height.

The contact holes (an opening, a connection hole) 22 penetrating the insulating film 21 are formed in the insulating film 21 and plugs (contact electrode) 23 are formed inside the contact holes 22. The plug 23 is composed of a conductive barrier film 23a formed of a titanium film, a titanium nitride film, or a laminated film thereof on the bottom surface and sidewall of the contact hole 22 and a tungsten (W) film (main conductive film) 23b formed on the conductive barrier film 23a so as to fill the inside of the contact hole 22. The contact holes 22 and the plugs 23 are formed on n⁺ type semiconductor regions 19a and 19b, a p⁺ type semiconductor region 19c, and on gate electrodes 16a, 16b and 16c. At the bottom of the contact holes 22, (the metal silicide layer 15 adjacent to) the n⁺ type semiconductor regions 19a and 19b, the p⁺ type semiconductor region 19c and the gate electrodes 16a, 16b and 16c are exposed, and the plugs 23 are electrically connected thereto.

An insulating film 24 formed of a silicon oxide film is formed on the insulating film 21 in which the plugs 23 are embedded, and the wirings (first wiring layer) 27 as a first layer interconnection are formed inside the wiring trench (opening) formed in the insulating film 24. The wiring 27 is composed of a conductive barrier film 26a formed of a titanium film, a titanium nitride film, or a laminated film thereof on the bottom surface and the sidewall of the wiring trench and a main conductive film 26b formed of a tungsten film or the like on the conductive barrier film 26a so as to fill the inside of the wiring trench. The wirings 27 are electrically connected to the n⁺ type semiconductor regions 9a and 9b, the p⁺ type semiconductor region 9c, and the gate electrodes 6a, 6b and 6c via the plugs 23. In the memory region 1A, the wiring 27 connected to the semiconductor region 22 (n⁺ type semiconductor region 19a) for the sources of the MISFETs QM1 and QM2 via the plug 23 forms a source wiring 27b.

On the insulating film 24 in which the wiring 27 is embedded, an insulating film (interlayer insulation film) 31 formed of a silicon oxide film is formed. A film for preventing peeling (separation) 32 is formed on the upper surface of the insulating film 31. The film for preventing peeling (interface peeling prevention layer) 32 is made of oxide of transition metal (tantalum oxide or the like) such as a material with a composition close to Ta₂O₅.

In the insulating film 31 and the film for preventing peeling 32 in the memory region 1A, the through hole (opening, connection hole, via hole) 34 penetrating therethrough is formed, and a plug (contact electrode, conductor portion) 35 is formed in the through hole 34. The plug 35 is composed of a conductive barrier film 35a formed of a titanium film, a titanium nitride film, or a laminated film thereof on the bottom surface and the sidewall of the through hole 34 and a tungsten (W) film (main conductive film) 35b formed on the conductive barrier film 35a so as to fill the inside of the through hole 34. Therefore, the plug 35 is a conductor portion formed (embedded) in the opening (through hole 34) of the interlayer insulation film (insulating film 31), and is an electrode (conductive plug) in the shape of a plug such as a cylindrical column, a rectangular column, a cylinder, or a rectangular pipe. The through hole 34 and the plug 35 are formed on a wiring 27a of the wiring 27, the wiring 27a being connected via the plug 23 to the semiconductor regions 10 and 11 (n⁺ type semiconductor region 9a) for the drains of the MISFETs QM1 and QM2 in the memory region 1A, and the wiring 27a and the plug 35 are electrically connected.

In the memory region 1A, on the laminated film of the insulating film 31 and the film for preventing peeling 32 in which the plug 35 is embedded, a resistor element (memory element, storage element) 48 composed of: a second component releasing region (diffusion element supply layer, metal element supply layer, lower electrode layer) 45 made of the first and second components; the solid electrolyte region (storage layer, solid electrolyte material layer, solid electrolyte layer, recording layer) 46 adjacent to the second component releasing region 45 made of the first and second components; and an upper electrode (upper electrode film, upper electrode layer, metal film, upper electrode region) 47 adjacent to the solid electrolyte region 46 is formed. More specifically, the resistor element 48 is composed of the lamination pattern including the second component releasing region 45 made of the first and second components, the solid electrolyte region 46 and the upper electrode 47 formed in this order from the bottom. The resistor element 48 is formed in, for example, the stripe-shaped pattern. The resistor element 48 corresponds to a nonvolatile memory element (storage element). Also, the solid electrolyte region 46 is a recording layer (storage layer, storage element, nonvolatile storage element) for the information of the nonvolatile memory.

Although details will be described later, the second component releasing region 45 made of the first and second components is formed by, for example, processing a Cu—Ta—O film (corresponding to a material film 41 described later) made of copper (Cu), tantalum (Ta) and oxygen into a dome-shaped electrode portion 43 (hereinafter, “dome-shaped electrode portion 43” is simply referred to as “electrode portion 43” or “dome-shaped portion 43”), and filling the circumference of the dome-shaped electrode portion 43 with an insulating film (corresponding to insulating films 44 and 44a described later) so that the surface of the dome-shaped electrode portion 43 is exposed from the surface of the insulating film. The solid electrolyte region 46 is made of a chalcogenide material. An oxide material or an organic substance that can function as an electrolyte can also be used instead of a chalcogenide material. The upper electrode 47 is made of a conductive material such as a metallic material and can be formed of, for example, a tungsten (W) film or a tungsten alloy film.

As another structure, the upper electrode (47) may be microfabicated into the dome-shaped shape similar to that mentioned above. Alternatively, by providing the dome-shaped second component releasing region (45) made of the first component and the second component again between the solid electrolyte region (46) and the upper electrode (47), the dome-shaped portions (43) may be faced on the both sides of the solid electrolyte region (46). By this means, the second component that is released from the lower dome-shaped portion and reaches between the solid electrolyte region (46) and the upper electrode (47) enters the upper dome-shaped portion and stabilizes. Although the operation is not affected even if composition of the upper and lower dome-shaped portions is the same, different compositions are preferable. Elements can be disposed so that respective parts are in contact with each other within a flat surface parallel to the main surface of a wafer (a semiconductor substrate) instead of stacking up in the direction perpendicular to the main surface of the wafer (semiconductor substrate 1), that is, in the thickness direction as mentioned above. The configuration of the resistor element 48 will be described in more detail later.

The lower part (lower surface) of (the electrode portion 43 of) the second component releasing layer 45 made of the first and second components of the resistor element 48 is electrically connected to the plug 35, and is electrically connected to the semiconductor regions 10 and 11 (drain region, n⁺ type semiconductor region 9a) of the MISFETs QM1 and QM2 for selecting memory cells in the memory region 1A via the plug 35, the wiring 27a, and the plug 23. Therefore, the plug 35 is electrically connected to the lower surface side of (the electrode portion 43 of) the second component releasing region 45 made of the first and second components.

Moreover, the film for preventing peeling 32 is interposed between the laminated film including the second component releasing layer 45 made of the first and second components, the solid electrolyte region (solid electrolyte layer) 46 and the upper electrode (upper electrode layer) 47 and the insulating film 31 so as to improve the adhesion (adhesiveness) therebetween and to prevent the laminated film including the second component releasing layer 45 made of the first and second components, the solid electrolyte region (solid electrolyte layer) 46 and the upper electrode (upper electrode layer) 47 from separating from the insulating film 31. The formation of the film for preventing peeling 32 can be omitted if it is unnecessary.

An insulating film 51 is formed on the upper surface of the resistor element 48, that is, on the upper surface of the upper electrode 47. The insulating film 51 is formed of a silicon oxide film, and is an insulating film used as a hard mask (etching mask) when patterning the resistor element 48. Therefore, the insulating film 51 is formed in the same pattern as the resistor element 48, for example, in the stripe shape in the same manner as the resistor element 48. The formation of the insulating film 51 can be omitted when the resistor element 48 is patterned using a photoresist pattern.

On the laminated film of the insulating film 31 and the film for preventing peeling 32, an insulating film (interlayer insulation film) 52 formed of a silicon oxide film is formed so as to cover the resistor element 48 and the insulating film 51. The upper surface of the insulating film 52 is evenly formed so that the memory region 1A and the peripheral circuit region 1B have almost the same height.

In the memory region 1A, a through hole (opening, connection hole, via hole) 53 is formed in the insulating films 51 and 52, and at least a part of the upper electrode layer 47 of the resistor element 48 is exposed on the bottom surface of the through hole 53. A plug (contact electrode, conductor portion) 54 is formed inside the through hole 53. The plug 54 is composed of a conductive barrier film 57a formed of a titanium film, a titanium nitride film, or a laminated film thereof on the bottom surface and the sidewall of the through hole 53 and a tungsten (W) film (main conductive film) 57b formed on the conductive barrier film 57a so as to fill the inside of the through hole 53. An aluminum film can also be used instead of the tungsten film 57b. The through hole 53 and the plug 54 are formed on the resistor element 48, and the plug 54 is electrically connected to the upper electrode layer 47 of the resistor element 48. Therefore, the plug 54 is formed (embedded) in the opening (through hole 53) of the insulating film 52 serving as an interlayer insulation film, is a conductor portion electrically connected to the upper electrode layer 47, and is an electrode (conductive plug) in the shape of a plug such as a cylindrical column, a rectangular column, a cylinder, or an rectangular pipe.

In the peripheral circuit region 1B, the through hole (opening, connection hole, via hole) 55 is formed in the insulating film 31, the film for preventing peeling 32, and the insulating film 52 so as to penetrate therethrough, and the upper surface of the wiring 27 is exposed on the bottom surface of the through hole 55. A plug (contact electrode) 56 is formed inside the through hole 55. The plug 56 is composed of the conductive barrier film 57a formed of a titanium film, a titanium nitride film, or a laminated film thereof formed on the bottom surface and the sidewall of the through hole 55 and the tungsten film (main conductive film) 57b formed on the conductive barrier film 57a so as to fill the inside of the through hole 55. The through hole 55 and the plug 56 are electrically connected to the wiring 27.

On the insulating film 52 in which the plugs 54 and 56 are embedded, the wiring (second wiring layer) 62 as a second layer interconnection is formed. The wiring 62 is composed of, for example, a conductive barrier film 61a formed of a titanium film, a titanium nitride film, or a laminated film thereof and an aluminum (Al) film or an aluminum alloy film (main conductive film) 61b adjacent to the conductive barrier film 61a. Alternatively, a conductive barrier film similar to the conductive barrier film 61a may be further formed on the aluminum alloy film 61b to form the wiring 62.

In the memory region 1A, the wiring (bit line) 62a of the wiring 62 is electrically connected to the upper electrode layer 47 of the resistor element 48 via the plug 54. Therefore, the wiring 62a constituting the bit lines (corresponding to the bit lines BL1, BL2, BL3, and BL4) in the memory region 1A is electrically connected to the semiconductor regions (drain region) 20 and 21 (n⁺ type semiconductor region 19a) of the MISFETs QM1 and QM2 for selecting memory cells in the memory region 1A via the plugs 54, the resistor element 48, the plugs 35, the wirings 27a, and the plugs 23.

In the peripheral circuit region 1B, the wiring 62 is electrically connected to the wiring 27 via the plug 56, and is further electrically connected to the n⁺ type semiconductor region 9b of the MISFET QN and the p⁺ type semiconductor region 9c of the MISFET QP via the plugs 23.

An insulating film (not shown) serving as an interlayer insulation film is formed on the insulating film 52 so as to cover the wiring 62, and upper wiring layers (wirings for the third and subsequent layer interconnections) are further formed, but illustrations and descriptions thereof are omitted here.

In this manner, a semiconductor integrated circuit including a memory (nonvolatile memory, memory cell) in the memory region 1A and the MISFETs in the peripheral circuit region 1B is formed on the semiconductor substrate 1 to form a semiconductor device of the present embodiment.

As described above, the resistor element 48 and the MISFETs QM1 and QM2 as memory cell transistors (transistor for selecting memory cells) connected to the resistor element 48 constitute the memory cells of the nonvolatile memory. The gate electrodes 6a of the MISFETs QM1 and QM2 are electrically connected to the word lines (corresponding to the word lines WL1 to WL4). The upper surface side of the resistor element 48 (upper surface side of the upper electrode layer 47) is electrically connected to the bit lines (corresponding to the bit lines BL1 to BL4) composed of the wiring 62a via the plug 54. The lower surface side of the resistor element 48 (lower surface side of the second component releasing layer 45 made of the first and second components) is electrically connected to the semiconductor regions 10 and 11 for drains of the MISFETs QM1 and QM2 via the plug 35, the wiring 27a and the plug 23. The semiconductor region 12 for the source of the MISFETs QM1 and QM2 is electrically connected to the source wiring 27b (source line) via the plug 23.

Note that, in the present embodiment, the n channel MISFETs QM1 and QM2 are used as memory cell transistors (transistors for selecting memory cells), but in another embodiment, other field effect transistors such as a p channel MISFET can also be used instead of the n channel MISFETs QM1 and QM2. However, the MISFET is preferably used as a memory cell transistor from a viewpoint of high integration, and the n channel MISFETs QM1 and QM2 with a small channel resistance in an ON state are more preferable than the p channel MISFET.

In addition, in the present embodiment, the resistor element 48 is electrically connected to the drain (semiconductor regions 10 and 11) of the MISFETs QM1 and QM2 in the memory region 1A via the plug 35, the wiring 27 (27a) and the plug 23, but in another embodiment, the resistor element 48 can also be electrically connected to the source of the MISFETs QM1 and QM2 in the memory region 1A via the plug 35, the wiring 27 (27a) and the plug 23. More specifically, the resistor element 48 is electrically connected to either of the drain or the source of the MISFETs QM1 and QM2 in the memory region 1A via the plug 35, the wiring 27 (27a) and the plug 23. However, it is more preferable that the drain rather than the source of the MISFETs QM1 and QM2 in the memory region 1A is electrically connected to the resistor element 48 via the plug 23, the wiring 27 (27a) and the plug 35 in consideration of the function as a nonvolatile memory.

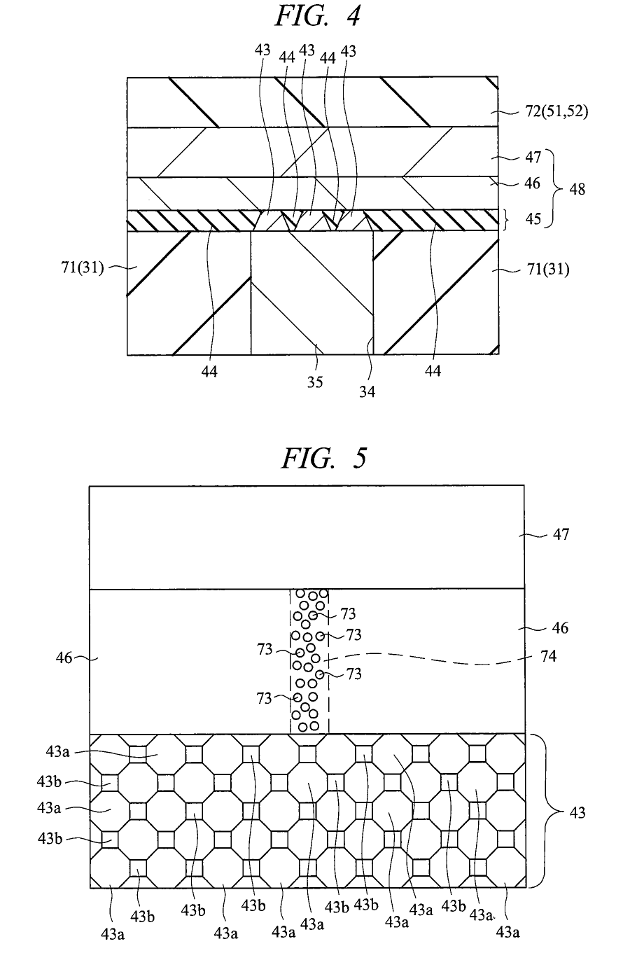

Next, the resistor element 48 that is a storage element (memory element) of the semiconductor device according to the present embodiment will be described in more detail. FIG. 4 is a sectional view showing the principal part in the vicinity of the resistor element 48 of the semiconductor device of FIG. 3. FIG. 5 is a sectional view (partially enlarged sectional view, schematic view) showing the principal part of the resistor element 48, in which the state of the electrode portion 43 of the second component releasing region 45 made of the first and second components, the solid electrolyte region 46 and the upper electrode 47 adjacent thereto is schematically shown. Although FIG. 5 is a sectional view, hatching is omitted for the purpose of making the drawing easy to see.

As shown in FIG. 4, the resistor element 48 that functions as a storage element is composed of the second component releasing region 45 made of the first and second components, the solid electrolyte region 46 adjacent to the second component releasing region 45 made of the first and second components, and the upper electrode 47 adjacent to the solid electrolyte region 46. In FIG. 4, the second component releasing region 45 made of the first and second components, the solid electrolyte region 46, and the upper electrode 47 are formed on an insulating film 71 in which the plug 35 is embedded, and an insulating film 72 is formed thereon. The insulating film 71 of FIG. 4 corresponds to the insulating film 31 of FIG. 3, and the insulating film 72 of FIG. 4 corresponds to the insulating films 51 and 52 of FIG. 3. In addition, in the illustration of FIG. 4, the film for preventing peeling 32 is included in the insulating film 71.

The second component releasing region 45 made of the first and second components, the solid electrolyte region 46, and the upper electrode 47 are the patterns disposed on the plug 35. The current path between the plug 35 and the upper electrode 47 is the second component releasing region 45 (electrode portion 43) made of the first and second components and the solid electrolyte region 46 in the region above the plug 35, and the second component releasing region 45 made of the first and second components and the solid electrolyte region 46 apart from the plug 35 hardly function as a current path. Therefore, the second component releasing region 45 (electrode portion 43) made of the first and second components, the solid electrolyte region 46 and upper electrode 47 in the region above the plug 35 form the resistor element 48. Therefore, even if the laminated pattern of the second component releasing region 45 made of the first and second components, the solid electrolyte region 46 and the upper electrode 47 is formed as a stripe pattern passing above a plurality of plugs 35 as shown in FIG. 3 mentioned above, the second component releasing region 45 (electrode portion 43) made of the first and second components, the solid electrolyte region 46 and the upper electrode 47 in the region above each plug 35 can form the resistor element 48 for each of the plugs 35. In addition, the resistor element 48 can be formed into independent patterns by dividing a laminated pattern of the second component releasing region 45 made of the first and second components, the solid electrolyte region 46 and the upper electrode 47 for each memory cell (each of the plugs 35).

The second component releasing region 45 made of the first and second components has the structure in which the dome-shaped electrode portions (releasing portion, dome-shaped portion, second component releasing portion, second component releasing cell) 43 are surrounded by and embedded in the insulator region (insulating film 44). The insulating film (insulator region) 44 filling the circumference of the dome-shaped electrode portion 43 is formed of, for example, an insulator such as silicon oxide or aluminum oxide. The top part (upper surface, upper part) of the electrode portion 43 is exposed from the surface (upper surface) of the insulating film 44. In the present embodiment, a columnar shape (such as a cylindrical column or a rectangular column), a projecting shape, convex and hemispherical shapes are called dome-shaped. The top part of the electrode portion 43 faces (is adjacent to) the solid electrolyte region 46, and the side of the dome-shaped portion 43 opposite to the side facing the solid electrolyte region 46 (top part of the electrode portion 43), that is, the lower part of the electrode portion 43 faces (is adjacent to) and is electrically connected to the plug 35. The insulating film 44 is made from an insulator, and thus does not function as a current path.

As schematically shown in FIG. 5, the dome-shaped portion (dome-shaped electrode portion, second component releasing portion, second component releasing cell) 43 contains (is formed of) first portions 43a made of the first component and second portions 43b made of the second component. In FIG. 5, although the first portions 43a are schematically shown as regular octagons and the second portions 43b are schematically shown as regular tetragons, these shapes are merely conceptual, and the actual shape of each of the parts 43a and 43b is not limited thereto.

The first component that constitutes the first portions 43a of the dome-shaped portion 43 is made of a compound of metal or semiconductor and at least one element from the group including oxygen, sulfur, selenium, tellurium, nitrogen and carbon. The second component that constitutes the second portions 43b of the electrode portion 43 is made of at least one element selected from the group including metal such as copper (Cu) and silver (Ag) and metalloid elements.

A material that is stable and hard to be changed even if an electric field (voltage) is applied and is hard to be diffused (not diffused) in the solid electrolyte region (solid electrolyte layer) 46 is used for the first component, and a material that is more easily diffused in the solid electrolyte region (solid electrolyte layer) 42 by the application of an electric field (electrical field, voltage) and is more easily able to move in the solid electrolyte region (solid electrolyte layer) 42 is used for the second component. Therefore, the binding force of the first component is preferably stronger than that of the second component, and the melting point of the first component is preferably higher than that of the second component. In other words, it is preferable that the binding force of metal or semiconductor with at least one element from the group including oxygen, sulfur, selenium, tellurium, nitrogen and carbon in the first component is stronger than the binding force with at least one element from the group including oxygen, sulfur, selenium, tellurium, nitrogen and carbon in the second component.

In addition, the first component is preferably made of oxide (oxide of metal or semiconductor), and the first component is more preferably oxide of tantalum (Ta) (that is, tantalum oxide such as Ta₂O₅). By this means, the first portion 43a made of the first component can be more stable and hard to be changed, and the stability of the dome-shaped portion 43 can be further improved. Therefore, the main component of the first component (first portion 43a) is more preferably tantalum oxide.

The first portion 43a made of the first component (for example, tantalum oxide) is microscopic particles (fine particles) or microcrystals of the first component (oxide of metal or semiconductor such as tantalum oxide). These microscopic particles or microcrystals are formed in various heating processes of the semiconductor device manufacturing process.

The second component is metal or metaloid atoms that are diffused from the electrode portion 43 into the solid electrolyte region (solid electrolyte layer) 46 adjoining (adjacent) to the electrode portion 43 to form a conducting path in the solid electrolyte region (solid electrolyte layer) 46. For example, the second component is preferably copper (Cu) or silver (Ag) as mentioned above. As schematically shown in FIG. 5, the second portions 43b made of the second component (copper or silver) exist in the gaps (spaces) between the first portions 43a made of the first component (for example, tantalum oxide) in the electrode portion 43. It is more preferable that the second portions 43b exist in the gaps (spaces) between the first portions 43a in a metal state. That is, in the electrode portion 43, for example, metal (or metaloid) such as copper or silver (the second component, the second portion 43b) exists in the gaps (spaces) between the plurality of microscopic particles or microcrystals (the first portion 43a) of oxide such as tantalum oxide (first component).

When the second component is copper (Cu), since copper (Cu) is used in the manufacturing process (for example, in a process of forming embedded copper wiring) of the semiconductor device, there is little fear of the metallic contamination and others. Also, when the second component is silver (Ag), since silver (Ag) has an ionic radius smaller than copper (Cu) and has a faster diffusion rate, the diffusion rate of the second component from the electrode portion 43 into the solid electrolyte region 46 at the time of writing can be increased, and the writing speed can be improved.

The planar dimension (area) of the electrode portion 43 located on the plug 35 is smaller than the planar dimension (area) of the upper surface of the plug 35. Further, the contact area of the dome-shaped portion 43 located on the plug 35 and the solid electrolyte region 46 is smaller than the area of the upper surface of the plug 35.

It is more preferable that the plurality of dome-shaped portions 43 are formed in the region adjacent to the plug 35, but when the diameter (for example, the diameter of the plug 35) of the upper surface of the plug 35 (contact electrode) is extremely small, it does not matter if only one electrode portion 43 is located on the plug 35. However, if the dome-shaped portion 43 does not exist on the plug 35, the function as a memory element cannot be achieved, and thus at least one dome-shaped portion 43 has to be formed on the plug 35. More specifically, the second component releasing layer 45 made of the first and second components is formed on the insulating film 71 including the plugs 35, and at least one dome-shaped portion 43 exists on the plug 35. Therefore, the part of the second component releasing region 45 made of the first and second components located on the plug 35 is composed of at least one dome-shaped portion 43 and the insulating film 44 around it. The dome-shaped portion 43 located on the plug 35 functions as one electrode (lower electrode, second component releasing cell) of the memory element (storage element), and a part of the upper electrode layer 47 that faces the dome-shaped portion 43 adjacent to the plug 35 via the solid electrolyte region 46 functions as the other electrode (upper electrode, second electrode) of the memory element (storage element).

The electrode portion 43 of the second component releasing region 45 made of the first and second components is a supply layer of metal ions or metal elements (the second component) that move (are diffused) in the solid electrolyte region 46, that is, a metal element supply layer. The solid electrolyte region 46 is a solid electrolyte layer where the second component (copper or silver) supplied from the electrode portion 43 moves (is diffused), and can function as an information recording (storage) layer. In this and other embodiments, a solid electrolyte means a solid electrolyte in a broad sense, and any material is available as long as some charge transfer in which the resistance change is detected can be generated.

Since the solid electrolyte region 46 is provided adjacent to the second component releasing region 45 made of the first and second components, the solid electrolyte region 46 exists adjacent to the dome-shaped electrode portion (second component releasing cell) 43. The solid electrolyte region 46 is preferably formed of a chalcogenide layer made a material containing a chalcogen element (S, Se, and Te) such as chalcogenide (chalcogenide semiconductor, chalcogenide material) because the rewriting speed of the memory element can be increased. Chalcogenide mentioned here means a material containing at least one element from sulfur (S), selenium (Se), and tellurium (Te). For example, by using sulfide of polyvalent metal for the solid electrolyte region 46 as a solid electrolyte layer or using Mo—S (Mo (molybdenum) and S (sulfur)) as a main component thereof, the rewrite operation of the memory element can be stabilized. Alternatively, the chalcogenide (sulfide, selenide, telluride) of other transition metals such as Ta (tantalum) and Ti (titanium) can also be used for the solid electrolyte region 46. As described above, the solid electrolyte region (solid electrolyte layer) 46 can be formed of chalcogenide and is preferably formed of chalcogenide containing at least one element selected from the group including tantalum, molybdenum and titanium and a chalcogen element, and it is more preferable that the chalcogen element contained in the solid electrolyte region 46 is sulfur (S). In this manner, since the melting point of the chalcogenide (solid electrolyte region 46) is increased and the chalcogenide becomes a more stable compound, the solid electrolyte region 46 can be stabilized and rewriting characteristics and others of the stored information of the solid electrolyte region 46 can be further improved.

Further, it is more preferable if the solid electrolyte region 46 contains the second component (copper or silver) contained in the electrode portion 43. If the solid electrolyte region 46 contains the second component (copper or silver), the diffusion (movement) of the second component (copper or silver) from the electrode portion 43 to the solid electrolyte region 46 at the time of writing can be induced or accelerated, and the writing speed can be further improved. Therefore, the solid electrolyte region 46 is more preferably formed of at least one element selected from the group including tantalum, molybdenum and titanium, a chalcogen element (preferably sulfur (S)) and a copper (Cu) element. Moreover, it is further preferable that the solid electrolyte region 46 is formed of a Cu—Mo—S film made of a copper (Cu) element, a molybdenum (Mo) element and a sulfur (S) element.

In the present embodiment, the solid electrolyte region (solid electrolyte layer) 46 is formed of chalcogenide, but in another embodiment, the solid electrolyte region 46 can be formed of oxide (solid electrolyte oxide, for example, tungsten oxide such as WO₃ or tantalum oxide such as Ta₂O₅) or an organic substance. In other words, a solid electrolyte oxide layer can be used as the solid electrolyte region 46, and in this case, although the rewriting speed of the memory decreases compared to the case where chalcogenide is used as the solid electrolyte region 46, the memory operation can be achieved. As mentioned above, the solid electrolyte region (solid electrolyte layer) 46 can be formed of oxide, preferably oxide containing at least one element selected from the group including tungsten (W) and tantalum (Ta) and an oxygen element, or an organic substance. Therefore, the solid electrolyte region 46 is a layer having chalcogenide, oxide, or an organic substance as a main component, that is, a chalcogenide layer, an oxide layer, or an organic layer.

Since a material that can be more easily diffused into and move in the solid electrolyte region 42 by the application of an electric field compared to the first component is used as the second component constituting the second portion 43b of the electrode portion 43, the second component can diffuse from the electrode portion 43 into the solid electrolyte region 46 or return from the solid electrolyte region 46 to the electrode portion 43 by the application of an electric field. On the other hand, since a material that is stable and is hard to be changed or diffused into the solid electrolyte region 46 even if an electric field (electrical field) is applied is used as the first component constituting the first portion 43a of the electrode portion 43, the first component of the electrode portion 43 does not diffuse into the solid electrolyte region 46 even when the electric field is applied. Therefore, even when the second component goes in and out from the electrode portion 43, the shape of the electrode portion 43 can be maintained by the first portion 43a made of the first component.

The metal element (or metalloid element) supplied (diffused) from the electrode portion 43 to the solid electrolyte region 46, that is, the second component moves from a gap to a gap between atoms toward the upper electrode 47 (electrode couple) in the solid electrolyte region 46 (solid electrolyte layer) by an electric field (electrical field), thereby forming a conducting path (conductive path) in the solid electrolyte region 46. More specifically, as schematically shown in FIG. 5, metal elements (metallic elements, metallic atoms, metal ions, metalloid elements, metaloid atoms, or metalloid ions) 73 supplied from the second portion 43b of the electrode portion 43 move inside the solid electrolyte region 46 by an electrical field (electric field), and a part with a high concentration of metal elements 73 is formed in the solid electrolyte region 46. The part with the high concentration of the metal elements 73 connects the electrode portion 43 and the upper electrode 47, so that a conducting path (conductive path, low resistance part) 74 is formed. The metal element 73 is the second component (copper (Cu) or silver (Ag)). The conducting path 74 contains a high concentration of the metallic atoms (metal element 73), and electrons can easily move from the metallic atoms to the metallic atoms adjacent thereto, and thus, a low resistance can be achieved. Therefore, the conducting path 74 has a lower resistance than other parts in the solid electrolyte region 46. The conducting path 74 is formed in the solid electrolyte region 46 to connect (couple) the electrode portion 43 and the upper electrode (upper electrode region) 47, so that the resistance of the solid electrolyte region 46 is lowered and the resistance of the resistor element 48 is also lowered.

An example of the chemical reaction is as follows. From the state where the electrode portion 43 is “Ta₂O₅+Cu+Cu²⁺+2e⁻⁻” and the solid electrolyte region 46 is “2MoS₂”, Cu²⁺ in the electrode portion 43 moves from the electrode portion 43 to the solid electrolyte region 46, and the electrode portion 43 is changed to “Ta₂O₅+Cu” and the solid electrolyte region 46 is changed to “Cu²⁺+MoS₂+S+S²⁻.”

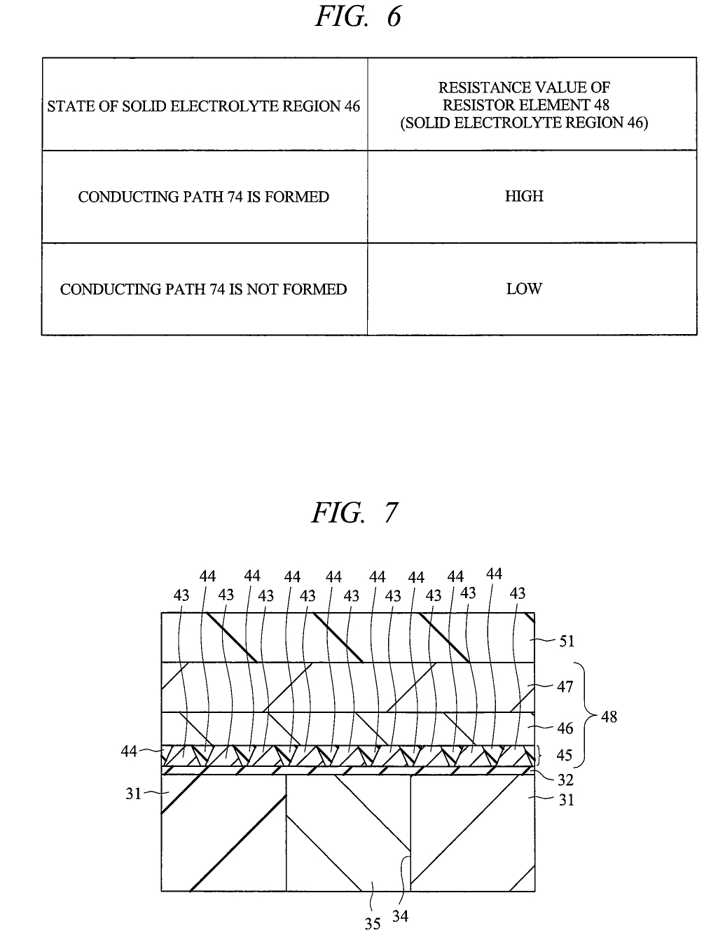

FIG. 6 is a table (diagram) showing the relation between the state of the solid electrolyte region 46 and the resistance value of the resistor element 48 (solid electrolyte region 46).

As shown in FIG. 6, when the conducting path 74 is not formed in the solid electrolyte region 46, the solid electrolyte region 46 has a high resistance, and thus the resistor element 48 also has a high resistance. However, when the conducting path 74 containing a high concentration of the metal element 73 (that is, the second component) is formed in the solid electrolyte region 46 so as to connect (couple) the electrode portion 43 and the upper electrodes 47, the resistance of the solid electrolyte region 46 is lowered, and the resistance of the resistor element 48 is also lowered. Therefore, by changing (transiting) the state of the solid electrolyte region 46 of each memory cell between the state without the conducting path 74 and the state with the conducting path 74, the resistance value (electrical resistivity) of the solid electrolyte region 46, that is, the resistance value of the resistor element 48 can be changed, and thus, a nonvolatile storage element (memory) can be formed. More specifically, with using the state whether the solid electrolyte region 46 has a high resistance (in the state without the conducting path 74) or the solid electrolyte region 46 has a low resistance (in the state with the conducting path 74) as stored information, information is stored in the solid electrolyte region 46 by the movement of the second component (metal element 73) inside the solid electrolyte region 46, which is supplied from the electrode portion 43 to the solid electrolyte region 46.

ON resistance and an OFF resistance of the resistor element 48 can be determined by a material and a film thickness of the two regions of (the electrode portion 43 of) the second component releasing region 45 made of the first and second components and the solid electrolyte region 46. In other words, the ON resistance is mainly determined by the resistance of the electrode portion 43 of the second component releasing region 45 made of the first and second components, and the OFF resistance is mainly determined by the resistance of the solid electrolyte region 46 (solid electrolyte layer). More specifically, when in an OFF state, since the conducting path is not formed in the solid electrolyte region 46 and the solid electrolyte region 46 is in a high resistance state, the OFF resistance is mainly determined by the resistance of the solid electrolyte region 46, and when in an ON state, since the conducting path 74 is formed in the solid electrolyte region 46 and the resistance of the solid electrolyte region 46 is lowered, the ON resistance is mainly determined by the resistance of the electrode portion 43 of the second component releasing region 45 made of the first and second components. Accordingly, the variation of the ON resistance and the OFF resistance caused when repeating the rewrite operation can be reduced. For example, the variation of the ON resistance and the OFF resistance caused when repeating the rewrite operation can be reduced to approximately ⅓ compared to a conventional memory element having the layers of Cu (lower electrode)-Cu₂S (solid electrolyte layer)-Pt (upper electrode).

The metal element 73 (that is, the second component) supplied from the dome-shaped portion 43 which is a metal element supply region (the second component releasing cell) to the solid electrolyte region 46 which is a solid electrolyte region can move in the solid electrolyte 46 by an electric field (electrical field). More specifically, since the metal element 73 exists in the solid electrolyte region 46 as a positive ion, when the electric potential of the upper electrode 47 is lower than the electric potential of the electrode portion 43 (and when the potential difference is larger than a predetermined threshold) by, for example, giving a negative electric potential to the upper electrode 47 and a positive electric potential to the electrode portion 43, the second component is diffused (supplied) from the electrode portion 43 to the solid electrolyte region 46, and the second component (metal element 73) attempts to move in the solid electrolyte region 46 toward the upper electrode 47 side. Also, when the electric potential of the upper electrode 47 is higher than the electric potential of the electrode portion 43 (and when the potential difference is larger than a predetermined threshold) by giving a positive electric potential to the upper electrode 47 and a negative electric potential to the electrode portion 43, the second component (metal element 73) moves in the solid electrolyte region 46 toward the electrode portion 43 side and attempts to be accepted in (the second portion 43b of) the electrode portion 43. Further, when the potential difference between the upper electrode (upper electrode region) 47 and the electrode portion 43 is zero or smaller than the predetermined threshold, the second component (metal element 73) does not move in the solid electrolyte region 46. Therefore, the electric field (electrical field) between the electrode portion 43 and the upper electrode (upper electrode region) 47 is controlled by controlling the voltage applied to the electrode portion 43 and the upper electrode (upper electrode region) 47, so that the movement of the second component (metal element 73) can be controlled, the transition between the high resistance state in which the conducting path 74 is not formed in the solid electrolyte region 46 and the low resistance state in which the conducting path 74 is formed in the solid electrolyte region 46 can be made, and each of the states can be maintained. Therefore, information can be stored (recorded) in the solid electrolyte region 46 with using the state whether the solid electrolyte region 46 has a high resistance without the conducting path 74 or the solid electrolyte region 46 has a low resistance with the conducting path 74 as stored information. Since the electrode portion 43 is electrically connected to the plug 35, the electric potential (voltage) of the electrode portion 43 can be controlled by the voltage applied to the plug 35 via the MISFETs QM1 and QM2 and others, and since the upper electrode 47 is electrically connected to the plug 54, the electric potential (voltage) of the upper electrode 47 can be controlled by the voltage applied to the plug 54 via the wiring 62 (62a) and others.

As described above, the second component (metal element 73) supplied from the electrode portion 43 (second component releasing cell) moves in the solid electrolyte region 46 to change the physical characteristics (electric resistance and others), thereby storing (recording) information in the solid electrolyte region 46. Also, the second component (metal element 73) supplied from the electrode portion 43 to the solid electrolyte region 46 moves in the solid electrolyte region 46 to change the physical characteristics (electric resistance and others), thereby rewriting information stored in the solid electrolyte region 46. In addition, stored information (high resistance or low resistance) in the solid electrolyte region 46 in the selected memory cell can be read by a passing current or the like of the selected memory cell to be accessed in an access operation. A specific example of the operation will be described in more detail later. The change of physical characteristic mentioned here means, for example, a change of an electric resistance between electrodes interposing the solid electrolyte region 46 therebetween (that is, between the electrode portion 43 and the upper electrode 47) and a change of an electric capacity. As described above, the change of an electric resistance is more preferable.

When the potential difference between the upper electrode 47 and the electrode portion 43 is zero or smaller than the predetermined threshold, the second component (metal element 73) does not move in the solid electrolyte region 46. Therefore, the information stored in the solid electrolyte region 46 (solid electrolyte) is maintained even if no power is supplied to the semiconductor device. Accordingly, the solid electrolyte region 46 or the resistor element 48 can function as a nonvolatile storage element.

The effect of the electrode (electrode portion 43) made of the metal-containing oxide used in the present embodiment is that, as shown in FIG. 5, metallic atoms (the second component) such as Cu and Ag that exist between microcrystals or microscopic particles (the second portion 43b) of oxide (the first component) are ionized and diffused in the chalcogenide region (solid electrolyte region 46) as ions with a small radius. Therefore, in the memory element structure of the present embodiment, the metallic atoms (metal element 73) forming the conducting path in the chalcogenide region (solid electrolyte region 46) exist in the gaps between the microscopic particles or microcrystals (second portion 43b) of oxide (the first component) in the adjoining region (dome-shaped portion 43) and the gaps (gaps between the first portions 43a) are small, so that the amount of metal ions (the second component, the metal element 73) such as Cu, Ag, or the like that are supplied from or returned to the electrode portion 43 can be restricted. In addition, it is also possible to achieve an effect of suppressing the film structure change (change of structure or shape of the electrode portion 43) caused by the movement of large ions (negative ions), clusters, and compounds such as S (sulfur), Se (selenium), Te (tellurium), Cu—S, Cu—Se, and Mo—S into the metal element supply region (electrode portion 43) at a portion of the chalcogenide region (solid electrolyte region 46) adjacent to the metal element supply region (electrode portion 43). Further, not all of the metals (second component, second portion 43b, that is, copper or silver) in the above-mentioned gaps (gaps between the first portions 43a) will move out as ions, and the conductivity of the electrode portion 43 is always maintained. The metal element supply region (electrode portion 43) corresponds to the electrode (metal electrode) of Ag or Cu in the conventional solid electrolyte memory. By the adoption of the new electrode film (electrode portion 43), the reliability in memory rewrite operation can be improved. In addition, the microfabrication of the part corresponding to the electrode makes it possible to utilize the electric field concentration for memory operation.

More specifically, in the present embodiment, as mentioned above, the electrode portion 43 is composed of the first portion 43a made of the first component that is stable and is not easily changed even by the application of an electric field and the second portion 43b made of the second component that can be easily diffused and moved in the solid electrolyte region 46 by an electric field. Accordingly, even when the second component (metal element 73) is repeatedly supplied from and returned to the electrode portion 43 in the repeated rewrite operation of the solid electrolyte information in the solid electrolyte region 46, the second portion 43b in the electrode portion 43 is hardly changed. Therefore, the shape of the electrode portion 43 is maintained, and the deformation or denaturalization of the electrode portion 43 can be prevented. Accordingly, the nonvolatile storage element (solid electrolyte memory) can be stably rewritten repeatedly.

Further, the proportion of the second component in the electrode portion 43 (electrode portion 43 located on the plug 35) (that is, the proportion of the second portion 43b made of the second component in the electrode portion 43) is preferably 30 atom % or higher. By this means, the second component (metal element 73) can be accurately supplied from the electrode portion 43 to the solid electrolyte region 46, and the storage of information in the solid electrolyte region 46 can be performed more accurately. Further, if the proportion of the first portion 43a made of the first component is extremely small in the electrode portion 43, the shape of the electrode portion 43 may be changed when rewrite operation is repeated. Therefore, the proportion of the first component in the electrode portion 43 (that is, the proportion of the first portion 43a made of the first component in the electrode portion 43) is preferably 30 atom % or higher. By this means, the shape stability of the electrode portion 43 when rewrite operation is repeated can be further improved, and the nonvolatile storage device (solid electrolyte memory) can be more stably rewritten repeatedly. Therefore, the proportion of the second component (second portion 43b) in the electrode portion 43 is preferably 30 atom % or higher and 70 atom % or lower (that is, within the range of 30 to 70 atom %), and in this manner, the storage characteristics of information in the solid electrolyte region 46 can be improved and the rewriting characteristics can be stabilized at the same time.

Further, in the present embodiment, since the metal element supply region (dome-shaped portion 43) is divided into minute dome-shaped portions (electrode portions 43) surrounded by the stable insulating materials (insulating films 44) as shown in FIG. 4, the contact area of the dome-shaped portion (electrode portion 43) and the solid electrolyte region 46 is small and the electrode portion 43 and the solid electrolyte region 46 are in point contact, so that the occurrence of the rewriting instability due to the variations in an in-plane direction can be prevented. In the stacked structure of a metal electrode of Ag and a chalcogenide layer in the conventional solid electrolyte memory, the diffusion of a metal element such as Ag into the chalcogenide layer becomes uneven due to the influence of the defect in the chalcogenide layer, and when rewrite operation is repeated, the diffusion unevenness becomes larger and the reproducibility of the resistance is lowered in some cases. However, in the structure of the present embodiment, since the metal element 73 is supplied and returned only through the tip portion (top part, contact part of the electrode portion 43 and the solid electrolyte region 46) of the minute dome-shaped electrode portion 43, the electric field is concentrated on that area, and the reproducibility can be enhanced.

Also, in the present embodiment, since the metal element 73 is supplied and returned only through the tip portion of the minute dome-shaped electrode portion 43, the reduction in drive voltage and drive current can be achieved, and a high-speed rewriting can be performed with the voltage of 1.5 V or lower. Also, the drive current can be decreased approximately to ⅓ compared to, for example, the conventional memory element having the layers of Cu (lower electrode)-Cu₂S (solid electrolyte layer)-Pt (upper electrode). The rewrite operation can be performed 10⁸ times or more.

Further, in the present embodiment, rewrite operation can be stabilized by using sulfide of polyvalent metal such as Mo, Ta or Ti or oxide of W or Ta for the solid electrolyte region (solid electrolyte layer 46).

Also, when the electrode portion 43 is not formed to be in a dome-shaped portion but is formed in a film shape, that is, even when the part of the insulating film 44 is replaced by the same composition as the electrode portion 43 in the second component releasing region 45 made of the first and second components and the whole part of the second component releasing region 45 made of the first and second components is formed of a film with the same composition as the electrode portion 43 (for example, Cu—Ta—O film), the operation as a memory device is possible in the same manner as the present embodiment. However, the electrode portion 43 is preferably formed to be the dome-shaped portion as described in the present embodiment because the number of rewritable times can be increased by one order of magnitude compared to the case where the electrode portion 43 is formed in a film shape instead of the dome shape.

Further, when the electrode portion 43 is formed in a film shape having a larger area than the upper surface of the plug 35, since the whole film located on the upper surface of the plug 35 functions as an electrode, positions (diffusion position) of metal elements supplied from and returned to the electrode vary, and there is the possibility that the reproducibility may decrease when rewrite operation of solid electrolyte information in the solid electrolyte region 46 is repeated. Therefore, as described in the present embodiment, it is preferable that the planar dimension (area) of the electrode portion 43 located on the plug 35 is smaller than the planar dimension (area) of the upper surface of the plug 35, and the contact area of the electrode portion 43 located on the plug 35 and the solid electrolyte region 46 is smaller than the area of the upper surface of the plug 35. By this means, the area of the contact portion of the electrode portion 43 and the solid electrolyte region 46 can be made smaller, and the position (diffusion position) of the metal element 73 supplied from and returned to the electrode portion 43 can be limited, so that reproducibility when rewrite operation of solid electrolyte information in the solid electrolyte region 46 is repeated can be improved. In addition, since the area of the contact portion of the electrode portion 43 and the solid electrolyte region 46 is made small, the drive voltage and drive current can be lowered, and the MISFETs QM1 and QM2 can be downsized. Accordingly, it is possible to provide advantageous effects for the downsizing and higher integration of semiconductor devices. In addition, high-speed ON/OFF switch can be performed easily.

Further, since the contact area of the electrode portion 43 located on the plug 35 and the solid electrolyte region 46 is made smaller than the area of the upper surface of the plug 35, the contact area of the electrode portion 43 and the solid electrolyte region 46 becomes smaller, and the positions of the metal element 73 supplied from and returned to the electrode portion 43 are limited. Therefore, the second component (metal element 73) diffused in the solid electrolyte region 46 from the electrode portion 43 can return to the electrode portion 43 through the same position. Accordingly, even when rewrite operation of solid electrolyte information in the solid electrolyte region 46 is repeated, the electrode portion 43 maintains the shape thereof to prevent the deformation of itself, and it is possible to prevent the concentration of the metal element 73 in the solid electrolyte region 46 from being excessively increased. As a result, it is possible to prevent a phenomenon in which the resistance becomes unchanged at an intermediate resistance between ON and OFF due to the excessively increased concentration of the metal element 73 in the solid electrolyte region 46 by the repetition of rewrite operations, and the nonvolatile storage element (solid electrolyte memory) can be stably rewritten repeatedly.

Also, in the semiconductor device of the present embodiment, when the memory (resistor element 48) is changed to the ON state with a low resistance, the conducting path 74 upwardly spreads in the solid electrolyte region 46 from the top part of the dome-shaped electrode portion 43, and since it resembles a spark plug of a gasoline engine igniting the gas in a cylinder, the memory (semiconductor memory, resistor element 48) can be called an ion plug memory.

Also, after manufacturing a semiconductor device, if a potential higher than the upper electrode 47 is first applied to the electrode portion 43 side (positive electric potential is given to the electrode portion 43 side) and then a large current is supplied between the electrode portion 43 and the upper electrode 47, thereafter, an operation mode in which the resistor element 48 (solid electrolyte region 46) is in a low resistance state is activated when a potential lower than the upper electrode 47 is applied to the electrode portion 43 side (negative electric potential is given to the electrode portion 43 side). Further, after manufacturing a semiconductor device, if a potential lower than the upper electrode 47 is first applied to the electrode portion 43 side (negative electric potential is given to the electrode portion 43 side) and then a large current is supplied between the electrode portion 43 and the upper electrode 47, thereafter, an operation mode in which the resistor element 48 (solid electrolyte region 46) is in a low resistance state is activated when a potential higher than the upper electrode 47 is applied to the electrode portion 43 side (positive electric potential is given to the electrode portion 43 side).

Further, since the film for preventing peeling 32 has an effect of peeling prevention if it has a thickness of approximately 1 to 2 nm, it can be formed after forming the plug 35, and the film for preventing peeling 32 can also be interposed between the second component releasing region 45 made of the first and second components (electrode portion 43) and the plug 35. FIG. 7 is a sectional view showing the principal part of the semiconductor device according to another embodiment, and it corresponds to FIG. 4 shown above. In FIG. 3 and FIG. 4, since the plug 35 is formed after forming the film for preventing peeling 32, the film for preventing peeling 32 is not interposed between the plug 35 and the second component releasing region 45 made of the first and second components, and the lower surface of the electrode portion 43 is in direct contact with the upper surface of the plug 35 and is electrically connected thereto. However, in FIG. 7, since the film for preventing peeling 32 is formed after forming the plug 35, the through hole 34 is formed in the insulating film 31, but does not penetrate the film for preventing peeling 32. Further, the film for preventing peeling 32 is formed so as to cover the upper surface of the plug 35 on the insulating film 31, and the laminated film of the second component releasing region 45 made of the first and second components, the solid electrolyte region 46 and the upper electrode 47 is formed on the film for preventing peeling 32. Therefore, in FIG. 7, the film for preventing peeling 32 is interposed between the upper surface of the plug 35 and the lower surface of the second component releasing region 45 made of the first and second components (electrode portion 43). However, by forming the film for preventing peeling 32 to have a small thickness (for example, approximately 1 to 2 nm), the film for preventing peeling 32 is not formed in a completely continuous manner in a plane thereof. Further, since current can be acquired also by the tunnel effect, even if the film for preventing peeling 32 is interposed between the plug 35 and the second component releasing region 45 made of the first and second components, the plug 35 and the second component releasing region 45 made of the first and second components (electrode portion 43) can be electrically connected (when applying voltage or the like).

In addition, as mentioned above, the part of the second component releasing region 45 made of the first and second components located on the plug 35 is composed of at least one electrode portion 43 and its surrounding insulating film 44. However, the part of the second component releasing region 45 made of the first and second components not located on the plug 35 can also be composed of the electrode portion 43 and its surrounding insulating film 44 or composed of only the insulating film 44. In other words, at least one electrode portion 43 has to be formed on the plug 35, but the electrode portion 43 is not always necessary in the part not located on the plug 35. Therefore, although the case where the electrodes 43 are formed only on the plug 35 has been illustrated in FIG. 4, the electrode portions 43 can be disposed not only on the plug 35 but also in the region not located on the plug 35 (for example, in the whole plane of the second component releasing region 45 made of the first and second components) as shown in FIG. 7. However, the electrode portion 43 that exists in the region not located on the plug 35 does not substantially function as an electrode of the memory element, and the electrode portion 43 that exists on the plug 35 substantially functions as an electrode of the memory element. This is because, even if voltage is applied between the plug 35 and the upper electrode 47, since the electrode portion 43 not located on the plug 35 is separated from the plug 35, the second component (copper or silver) is not diffused into the solid electrolyte region 46 from the electrode portion 43 not located on the plug 35, and the second component (copper or silver) is diffused into the solid electrolyte region 46 mainly from the electrode portion 43 located on the plug 35.

A dielectric material preferably used for the film for preventing peeling 32 (interface layer) is a material that contains one of germanium dioxide, germanium nitride, silicon oxide, silicon nitride, aluminum nitride, titanium nitride, aluminum oxide, titanium oxide, chromium oxide, tantalum oxide, molybdenum oxide, silicon carbide, and zinc sulfide as a main component (60% or more), or the mixed material thereof. The mixed film region is preferably in contact with one of the electrodes (electrode portion 43 or upper electrode 47), and since the filament is formed by positive ions, the mixed film region is most preferably provided so as to be in contact with the negative electrode in terms of the stability of memory operation. However, the memory operation can be achieved even if it is not in contact with any of the electrodes. When a mixed layer of a dielectric material and chalcogenide is used, in order to obtain the high-resistance effect, the content of chalcogenide has to be set to 60 mol % or less. In the present embodiment, as the film for preventing peeling 32, a film with a thickness of 5 nm and made of a mixture of Ta₂O₅ of 70% and a material of the solid electrolyte region of 30% is provided. By setting the film thickness within the range of 2 nm to 25 nm, the resistance ratio of 10 or more can be maintained and the more than twofold rise in resistance can be secured.

Next, an operation of the nonvolatile memory formed in the memory region 1A will be described in more detail.

A chalcogenide material is used as a material of the solid electrolyte region 46 in the resistor element 48 that functions as a storage element. The chalcogenide mentioned here means a material containing at least one element of sulfur (S), selenium (Se) and tellurium (Te). Characteristics of the memory using a chalcogenide material are described in, for example, the Non-Patent Document 1 mentioned above. When information ‘0’ is written into this storage element, a positive voltage is applied, and when ‘1’ is written, a negative voltage is applied. The pulse width thereof is 50 ns.

From the operation principle of the storage element as mentioned above, in order to prevent the stored information from being destroyed, the read operation must be performed while controlling the voltage to be lower than the threshold voltage Vth at highest. In reality, since the threshold voltage is dependent also on voltage applying time and tends to be lowered when the time is long, the voltage must be adjusted so as not to exceed the threshold voltage to prevent the occurrence of the switching to a low resistance state during a read time. So, the operation that is based on these principles and realizes a memory array configuration shown in FIG. 1 will be described below.

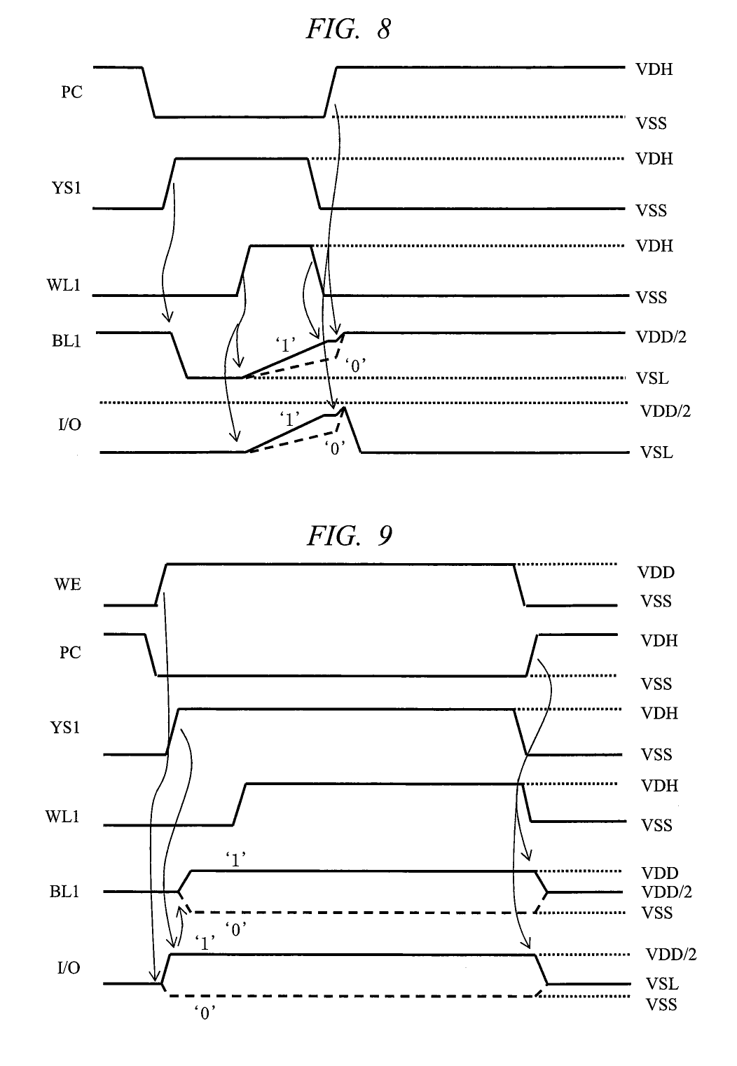

First, the read operation of the memory cell using the array configuration shown in FIG. 1 will be described with reference to FIG. 8. FIG. 8 shows the operation waveforms when selecting the memory cell MC11 (voltage application waveform).

First, since the precharge enable signal PC is maintained at the boost voltage VDH in a standby state, the n channel MIS transistors (MISFET) QC1 to QC4 are in a conducting state, and thus the bit lines BL1 to BL4 are maintained at the precharge voltage (VDD/2 here). Also, an input/output line I/O is precharged by the sense amplifier SA at the step-down voltage VSL (details will be described later).

When read operation starts, the precharge enable signal PC at the boost voltage VDH is driven to the ground voltage VSS, and the bit selection line YS1 at the ground voltage VSS is driven to the boost voltage VDH (1.5 or higher, for example). Therefore, the transistor (MISFET) QC1 is cut off and the transistor (MISFET) QD1 becomes conductive. At this time, the bit line BL1 is driven to the same step-down voltage VSL as the input/output line I/O. The step-down voltage VSL is higher than the ground voltage VSS and lower than the precharge voltage VDD/2, and the difference between the precharge voltage VDD/2 and the step-down voltage VSL is set to have a relation in which the terminal voltage of the resistor MR (R) falls within the range of a read voltage region.

Next, when the word line WL1 at the ground voltage VSS is driven to the boost voltage VDH, the selection transistors (MISFET) QM1 in all the memory cells on the word line WL1 become conductive. At this time, a current path is generated in the memory cell MC11 in which a potential difference is produced in the storage element MR, and the bit line BL1 is charged toward the precharge voltage VDD/2 at the speed in accordance with the resistance value of the storage element MR. In FIG. 8, since the resistance value is smaller when maintaining the stored information ‘1’ than when maintaining the stored information ‘0’, the charging is performed quickly. Therefore, a signal voltage in accordance with the stored information is generated. Since the potential difference of the storage element MR is 0 in the non-selected memory cells MC12 to MC14, the non-selected bit lines BL2 to BL4 are maintained at the precharge voltage VDD/2. In other words, only the memory cell MC11 selected by the word line WL1 and the bit line BL1 supplies a read current through the bit line BL1.

If bit lines or source lines of the memory array are put into a floating state in a standby state, when the bit line and the common bit line are connected at the time of starting a read operation, the capacitance of the bit line with an instable voltage is charged from the common bit line. Therefore, in FIG. 8, the bit selection line YS1 also falls in accordance with the word line WL1, and further, the precharge enable signal PC at the ground voltage VSS is driven to the boost voltage VDH, so that the bit line and the source line are driven to the precharge voltage VDD/2 to be in the standby state. Also, the boost voltage VDH is set so as to satisfy the relation of VDH>VDD+VTN by using the power supply voltage VDD and a threshold voltage VTN of the n channel MIS transistor. For example, in the write operation of a memory (ion plug memory), it is necessary to supply a current larger than that of a read operation as mentioned later. Therefore, in the present invention, the word line and the bit selection line are driven to the boost voltage VDH to lower the resistance of the n channel MIS transistor, thereby performing accurate write operations. Also, by setting the step-down voltage VSL to be lower than the precharge voltage VDD/2, the bit line is used as a source of a transistor (MISFET) QMm in the selected memory cell, and the voltage between the gate and the source of the transistor can be secured irrespective of the resistance of the storage element MR. Even in the case of reverse potential relation, if the difference is set to fall within the range of the read voltage region, the same select operation is possible.

Although an example of driving the word line WL1 after driving the source line CSL is shown in FIG. 8, the bit line BL1 can be driven after driving the word line WL1 for the convenience of design. In this case, since the word line WL1 is first driven and the selection transistor (MISFET) QM1 becomes conductive, the terminal voltage of the storage element MR is maintained at 0 V. Thereafter, when the bit line BL is driven, the terminal voltage of the storage element MR increases from 0 V, but since the value thereof is constrained by the bit line voltage, the value can fall within the range of the read voltage region.

In the example of selecting the memory cell MC11 described above, other memory cells on the same bit line will not be selected because the word line voltage thereof is fixed to the ground voltage VSS. Further, since the other bit lines are driven to the precharge voltage VDD/2, the rest of the memory cells are also maintained in the non-selected state.

In the above description, the word line in the standby state is at the ground voltage VSS, and the bit line in the selected state is at the step-down voltage VSL. The relation of the voltages must be set so that the current flowing through the non-selected memory cell does not affect the operations. More specifically, the voltage is adjusted so that the transistors (MISFET) QM of the memory cells whose bit lines are selected and word lines are not selected, for example, the transistors QM of the non-selected memory cells MC21 to MCn1 that are in a non-selected state when the memory cell MC11 is selected are sufficiently in an OFF state. As shown above, the threshold voltage of the transistor QM can be lowered by setting the word line voltage in the standby state to the ground voltage VSS and setting the step-down voltage VSL immediately before reading a selected bit line to a positive voltage. In some cases, it is also possible to set the selected bit line to the ground voltage VSS and set the word line in the standby state to a negative voltage. Also in such a case, the threshold voltage of the transistor (MISFET) QM can be lowered. Although the negative voltage has to be generated for the word lines in a standby state, since the voltage of the bit lines when selected is the ground voltage VSS applied from outside, it is easy to stabilize. If the threshold voltage of the transistor (MISFET) QM is sufficiently increased, the bit line when selected and the word line in the standby state can be set to the ground voltage VSS. In this case, since the ground voltage VSS applied from outside is used and further the capacitance of the word line in a standby state functions as a stabilizing capacitance, the voltage of the bit lines when selected can be further stabilized.

Next, the write operation of the memory cell using the array configuration shown in FIG. 1 will be described with reference to FIG. 9. FIG. 9 shows the operation waveforms (voltage application waveform) when selecting the memory cell MC11. First, after finishing the precharge, a rewriting enable signal WE at the ground voltage VSS is driven to the power supply voltage VDD to activate a rewriting circuit PRGCA, thereby driving the input/output line I/O to the voltage in accordance with the data to be written. FIG. 9 shows an example in which the input/output line I/O at the step-down voltage VSL is driven to the power supply voltage VDD when data “1” is written and the input/output line I/O at the step-down voltage VSL is driven to the ground voltage VSS when data ‘0’ is written. Next, the select operation of the memory cell MC11 is performed in the same manner as the read operation, and by driving the selected bit line BL1 to the same voltage as the input/output line I/O, a write current IWC is generated. When writing ‘0’, reset current flows through the memory cell MC11 from the common source line CSL to the bit line BL1. On the other hand, when writing ‘1’, set current flows through the memory cell MC11 from the bit line BL1 to the common source line CSL. By the above-mentioned configuration and operation, the rewrite operations of supplying a current in the direction in accordance with the data can be achieved. Since ideal ionic conduction can be performed by such operations, the setting time can be reduced and the number of rewritable times can be increased.

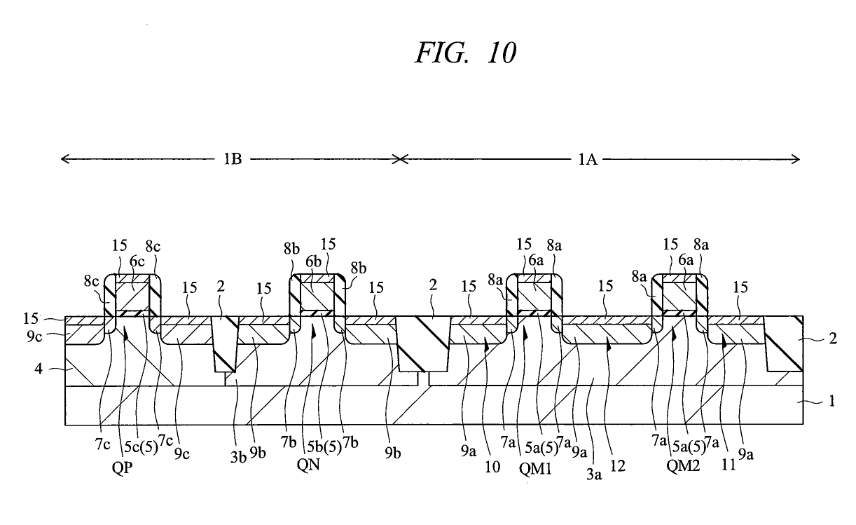

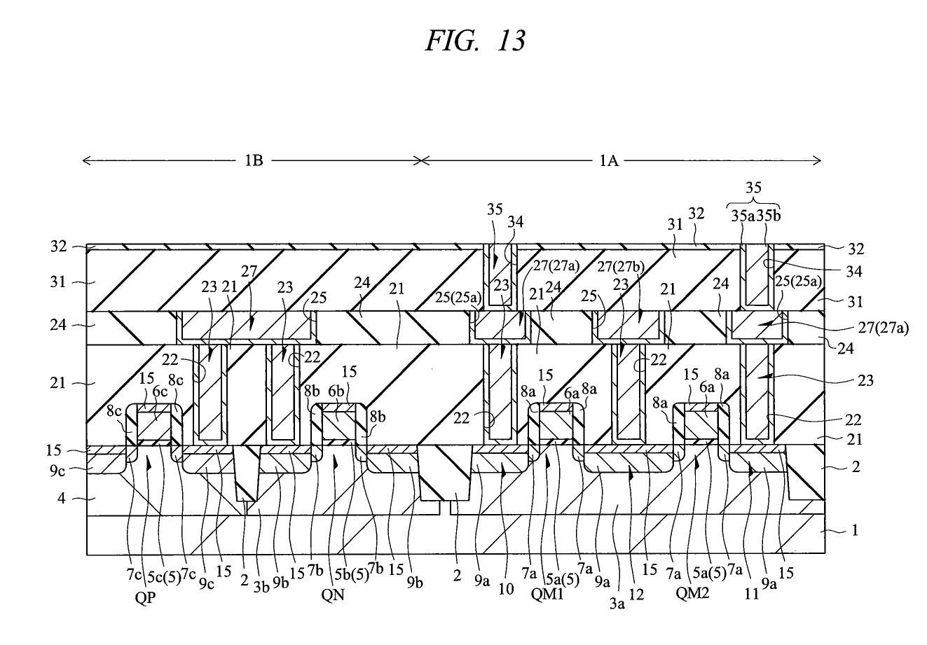

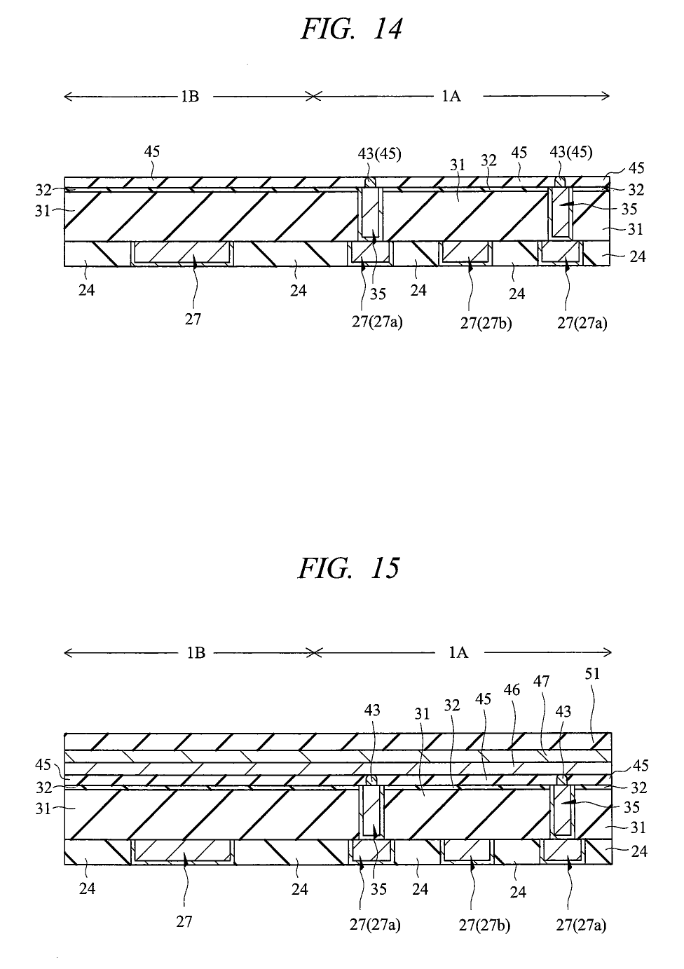

Next, the manufacturing process of the semiconductor device according to the present embodiment will be described with reference to the accompanying drawings. FIGS. 10 to 18 are sectional views showing the principal part of the semiconductor device during a manufacturing process according to the present embodiment, and the regions corresponding to FIG. 3 are shown therein. In FIGS. 14 to 18, the illustration of the part corresponding to the insulating film 21 and the structure below it of FIG. 13 is omitted for the sake of easy understanding.

First, as shown in FIG. 10, a semiconductor substrate (semiconductor wafer) 1 made of p type single crystal silicon or the like is prepared. Next, isolation regions 2 made of an insulator are formed in the main surface of the semiconductor substrate 1 by, for example, the STI (Shallow Trench Isolation) method or the LOCOS (Local Oxidization of Silicon) method. By forming the isolation regions 2, active regions whose perimeter is specified by the isolation regions 2 are formed in the main surface of the semiconductor substrate 1.

Next, p wells 3a and 3b and an n well 4 are formed in the main surface of the semiconductor substrate 1. The p well 3a is formed in the memory region 1A, and the p well 13b and the n well 14 are formed in the peripheral circuit region 1B. For example, the p wells 3a and 3b can be formed by an ion implantation of a p type impurity (for example, boron (B)) into a part of the semiconductor substrate 1, and the n well 4 can be formed by an ion implantation of an n type impurity (for example, phosphorus (P) or arsenic (As)) into the other part of the semiconductor substrate 1.

Next, an insulating film 5 for a gate insulating film formed of a thin silicon oxide film or the like is formed on the surface of the p wells 3a and 3b and the n well 4 of the semiconductor substrate 1 by the thermal oxidation method or the like. A silicon oxynitride film or the like can also be used as the insulating film 5. The film thickness of the insulating film 5 can be, for example, approximately 1.5 to 10 nm.

Next, the gate electrodes 6a, 6b and 6c are formed on the insulating films 5 of the p wells 3a and 3b and the n well 4. For example, a low-resistance polycrystalline silicon film is formed as a conductor film on the whole main surface of the semiconductor substrate 1 including the insulating film 5, and the polycrystalline silicon film is patterned using the photoresist method, the dry etching method and others, thereby forming the gate electrodes 6a, 6b and 6c formed of the patterned polycrystalline silicon film (conductor film). The insulating film 5 remaining under the gate electrode 6a functions as the gate insulating film 5a, the insulating film 5 remaining under the gate electrode 6b functions as the gate insulating film 5b, and the insulating film 15 remaining under the gate electrode 6c functions as the gate insulating film 5c. Note that, since impurities are doped when or after forming the films, the gate electrodes 6a and 6b are formed of the polycrystalline silicon film (doped polysilicon film) in which the n type impurity has been introduced, and the gate electrode 6c is formed of the polycrystalline silicon film (doped polysilicon film) in which the p type impurity has been introduced.

Next, by the ion implantation of an n type impurity such as phosphorus (P) or arsenic (As), n⁻ type semiconductor regions 7a are formed in the regions on both sides of the gate electrode 6a of the p well 3a, and n⁻ type semiconductor regions 7b are formed in the regions on both sides of the gate electrode 6b of the p well 3b. Further, by the ion implantation of a p type impurity such as boron (B), the p type semiconductor regions 7c are formed in the regions on both sides of the gate electrode 6c of the n well 4.

Next, the sidewalls 8a, 8b and 8c are formed on the sidewalls of the gate electrodes 6a, 6b and 6c. The sidewalls 8a, 8b and 8c can be formed by, for example, depositing an insulating film formed of a silicon oxide film, a silicon nitride film, or a laminated film thereof on the semiconductor substrate 1 and anisotropically etching the insulating film.

Next, by the ion implantation of an n type impurity such as phosphorus (P) or arsenic (As), the n⁺ type semiconductor regions 9a are formed in the regions on both sides of the gate electrode 6a and the sidewalls 8a of the p well 3a, and the n⁺ type semiconductor regions 9b are formed in the regions on both sides of the gate electrode 6b and the sidewalls 8b of the p well 3b. Further, by the ion implantation of a p type impurity such as boron (B), the p⁺ type semiconductor regions 9c are formed in the regions on both sides of the gate electrode 6c and the sidewalls 8c of the n well 4. Annealing treatment (heat treatment) for activation of the introduced impurities can be performed after the ion implantation.

In this manner, the n type semiconductor regions 10 and 11 that function as drain regions of the MISFETs QM1 and QM2 and the n type semiconductor region 12 that functions as a common source region of the MISFETs QM1 and QM2 in the memory region 1A are formed from the n⁺ type semiconductor regions 9a and the n⁻ type semiconductor regions 7a, respectively. Also, an n type semiconductor region that functions as a drain region of the MISFET QN and an n type semiconductor region that functions as a source region of the MISFET QN in the peripheral circuit region 1B are formed from the n⁺ type semiconductor regions 9b and the n⁻ type semiconductor regions 7b, respectively, and a p type semiconductor region that functions as a drain region of the MISFET QP and a p type semiconductor region that functions as a source region of the MISFET QP are formed from the p⁺ type semiconductor regions 9c and the p⁻ type semiconductor regions 7c, respectively.

Next, after the surfaces of the gate electrodes 6a, 6b and 6c, the n⁺ type semiconductor regions 9a and 9b, and the p⁺ type semiconductor region 9c are exposed, a metal film such as a cobalt (Co) film is deposited and the metal film is subjected to a thermal treatment. By this means, a metal silicide layer 15 is formed on each of the surfaces of the gate electrodes 6a, 6b and 6c, the n⁺ type semiconductor regions 9a and 9b, and the p⁺ type semiconductor region 9c. Then, the unreacted part of the cobalt film (metal film) is removed.

Thus, the structure of FIG. 10 is obtained. Through the process described above, the n channel MISFETs QM1 and QM2 are formed in the memory region 1A, and the n channel MISFET QN and the p channel MISFET QP are formed in the peripheral circuit region 1B. Therefore, the MISFETs QM1 and QM2 in the memory region 1A and the MISFETs QN and QP in the peripheral circuit region 1B can be formed in the same manufacturing process.

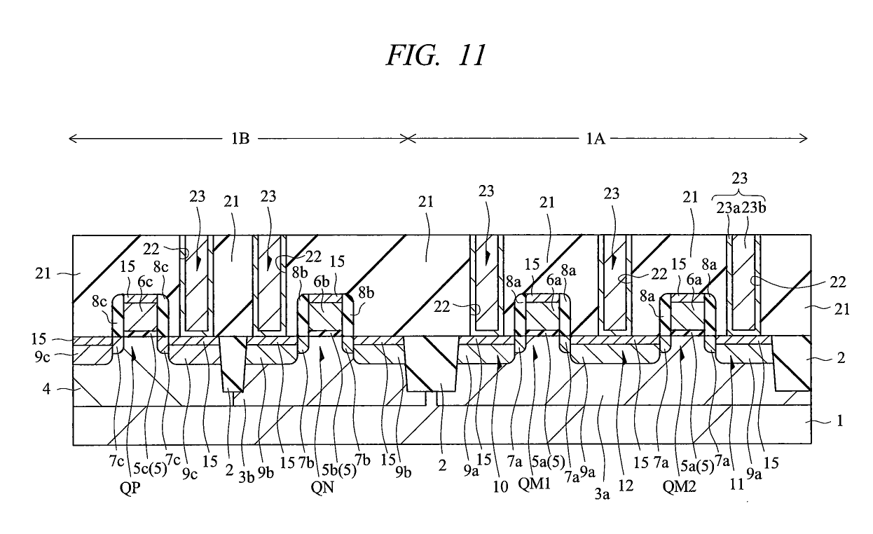

Next, as shown in FIG. 11, the insulating film (interlayer insulation film) 21 is formed over the semiconductor substrate 1 so as to cover the gate electrodes 6a, 6b and 6c. The insulating film 21 is formed of a silicon oxide film or the like. It is also possible to form the insulating film 21 from a laminated film of plural insulating films. After forming the insulating film 21, CMP treatment is performed as necessary to planarize the upper surface of the insulating film 21. By this means, the upper surface of the insulating film 21 has almost the same height in the memory region 1A and the peripheral circuit region 1B.

Next, the insulating film 21 is dry-etched with using a photoresist pattern (not shown) formed on the insulating film 21 by the photolithography method as an etching mask, thereby forming the contact holes 22 in the insulating film 21. A part of the main surface of the semiconductor substrate 1, for example, a part of (the metal silicide layer 25 adjacent to the surface of) the n⁺ type semiconductor regions 9a and 9b and the p⁺ type semiconductor region 9c and a part of (the metal silicide layer 15 adjacent to the surface of) the gate electrodes 6a, 6b and 6c are exposed on the bottom surfaces of the contact holes 22.

Next, the plugs 23 are formed in the contact holes 22. In this process, after forming the conductive barrier film 23a by a sputtering process or the like on the insulating film 21 including the inside of the contact holes 22, the tungsten film 23b is formed on the conductive barrier film 23a by the CVD method so as to fill the contact holes 22, and then the unnecessary part of the tungsten film 23b and the conductive barrier film 23a adjacent to the insulating film 21 is removed by the CMP method or the etch back method. In this manner, the plugs 23 formed of the tungsten film 23b and the conductive barrier film 23a that are left to be embedded in the contact holes 22 can be formed.

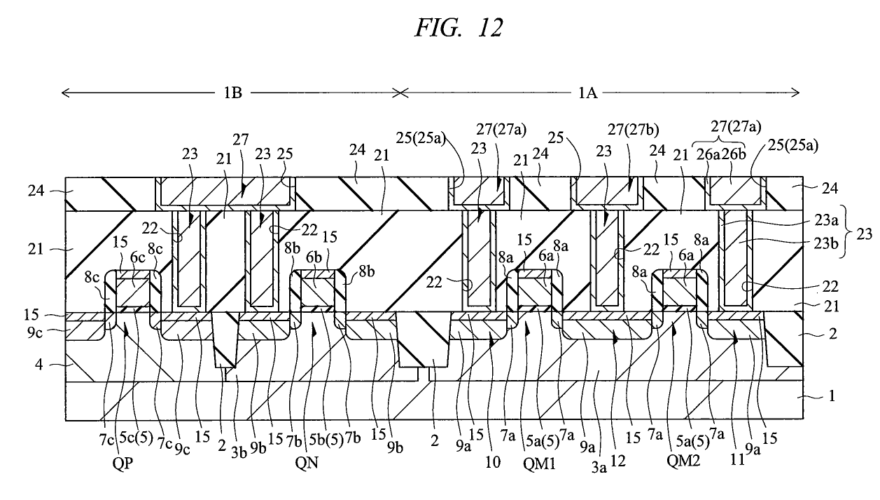

Next, as shown in FIG. 12, the insulating film 24 is formed on the insulating film 21 in which the plugs 23 are embedded. Then, the insulating film 24 is dry etched with using a photoresist pattern (not shown) formed on the insulating film 24 by the photolithography method as an etching mask, thereby forming wiring trenches (opening) 25 in the insulating film 24. The upper surfaces of the plugs 23 are exposed on the bottom surfaces of the wiring trenches 25. Note that, of the wiring trenches 25, the wiring trenches 25 from which the plugs 23 formed on the drain regions (semiconductor regions 20 and 21) of the MISFETs QM1 and QM2 in the memory region 1A are exposed, that is, the openings 25a can be formed as hole (connection hole) shaped patterns with a dimension larger than the planar dimension of the plugs 23 exposed therefrom instead of a trench pattern. In addition, although the openings 25a are formed simultaneously with other wiring trenches 25 in the present embodiment, the openings 25a and the other wiring trenches 25 can also be formed in different processes by using the photoresist pattern for forming the openings 25a and the photoresist pattern for forming the other wiring trenches 25 separately.

Next, the wirings 27 are formed in the wiring trenches 25. In this process, after forming the conductive barrier film 26a by the sputtering process or the like on the insulating film 24 including the inside (the bottom and the sidewall) of the wiring trenches 25, the main conductive film 26b formed of a tungsten film or the like is formed by the CVD method on the conductive barrier film 26a so as to fill the wiring trenches 25, and the unnecessary part of the main conductive film 26b and the conductive barrier film 26a adjacent to the insulating film 24 is removed by the CMP method or the etch back method. In this manner, the wirings 27 formed of the main conductive film 26b and the conductive barrier film 26a that are left to be embedded in the wiring trenches 25 can be formed.

Of the wirings 27, the wirings 27a formed in the openings 25a in the memory region 1A are electrically connected to the drain regions (semiconductor regions 10 and 11) of the MISFETs QM1 and QM2 in the memory region 1A via the plugs 23. The wiring 27a does not extend on the insulating film 21 and not connect the semiconductor elements formed on the semiconductor substrate 1, but it exists locally on the insulating film 21 to electrically connect the plug 35 and the plug 23 and is interposed between the plug 35 and the plug 23. Therefore, the wiring 27a can be regarded as a conductor part for connection (contact electrode) instead of a wiring. In addition, in the memory region 1A, the source wiring 27b connected via the plug 23 to the semiconductor region 12 (n⁺ type semiconductor region 9a) for the source of the MISFETs QM1 and QM2 is formed of the wiring 27.

The wiring 27 is not limited to the above-mentioned embedded tungsten wiring, but various modifications are possible. For example, a tungsten wiring, an aluminum wiring and others formed by the process other than the embedding process are available.

Next, as shown in FIG. 13, the insulating film (interlayer insulation film) 31 and the film for preventing peeling 32 are sequentially formed on the insulating film 24 in which the wirings 27 are embedded. The thickness of the film for preventing peeling 32 is smaller than the thickness of the insulating film 31. Further, the insulating film 31 can be formed of, for example, a silicon oxide film, and the film for preventing peeling 32 can be made of, for example, oxide of transition metal such as tantalum oxide (composition close to Ta₂O₅).

Next, the film for preventing peeling 32 and the insulating film 31 are dry etched with using a photoresist pattern (not shown) formed on the film for preventing peeling 32 by the photolithography method as an etching mask, thereby forming through holes (opening, connection hole, via hole) 34 in the film for preventing peeling 32 and the insulating film 31. The through holes 34 are formed in the memory region 1A, and the upper surfaces of the wirings 27a are exposed on the bottom surfaces of the through holes 34.

Next, the plugs 35 are formed in the through holes 34. In this process, for example, after forming the conductive barrier film 35a by the sputtering process or the like on the film for preventing peeling 32 including the inside of the through holes 34, a tungsten film 35b is formed on the conductive barrier film 35a by the CVD method so as to fill the through holes 34, and the unnecessary part of the tungsten film 35b and the conductive barrier film 35a adjacent to the film for preventing peeling 32 is removed by the CMP method or the etch back method. In this manner, the plugs 35 formed of the tungsten film 35b and the conductive barrier film 35a that are left to be embedded in the contact holes 34 can be formed. As described above, the plugs 35 are formed by filling the openings (through holes 34) formed in the film for preventing peeling 32 and the insulating film 31 with a conductive material.

In the present embodiment, the plug 35 is formed by filling the inside of the through hole 34 with the tungsten film 35b, but it is also possible to use a metal film that improves the planarity of the upper surface of the plug 35 when the CMP treatment is performed (metal with good CMP planarity) instead of the tungsten film 35b. As a metal with the good CMP planarity, for example, a molybdenum (Mo) film with a small crystal grain diameter can be used instead of the tungsten film 35b. By this means, the unevennesses on the upper surface of the plug 35 can be reduced, the uniformity of the electrical properties of the memory cell elements can be improved, and the reliability for the number of rewritable times and high-temperature resistant operation characteristics can be improved.

In another embodiment, after forming the insulating film 31, the through holes 34 and the plugs 35 are first formed without forming the film for preventing peeling 32, and then, the film for preventing peeling 32 is formed on the insulating film 31 including the upper surfaces of the plugs 35 (in the case of the structure as shown in FIG. 7).

Further, it is also possible to form a thin insulating film on the upper surface of the plug 35. For example, a silicon oxide film, a silicon nitride film, a germanium oxide film or an aluminum oxide film can be formed on the upper surface of the plug 35. Further, in order to increase the resistance of the upper surface of the plug 35, the surface (upper surface) of the tungsten film 35b constituting the plug 35 can be oxidized or nitrided to form a tungsten oxide film or a tungsten nitride film on the upper surface of the plug 35.

Next, as shown in FIG. 14, the second component releasing layer 45 made of the first and second components is formed on the film for preventing peeling 32 so as to cover the plug 35. The process of forming the second component releasing region 45 made of the first and second components will be described in more detail later. As mentioned above, in FIGS. 14 to 18, the part corresponding to the insulating film 21 and the structure below it of FIG. 13 is omitted.

Next, as shown in FIG. 15, the solid electrolyte region 46 is formed on the second component releasing region 45 made of the first and second components, and the upper electrode 47 is formed on the solid electrolyte region 46. The solid electrolyte region 46 is formed of a chalcogenide material film or the like, and the film thickness (deposited film thickness) thereof can be approximately 50 to 200 nm. The upper electrode 47 is formed of a conductor layer such as a metal layer, and a tungsten (W) film or a tungsten alloy film is used to form the upper electrode 47, and the film thickness (deposited film thickness) thereof can be approximately 50 to 200 nm.

Next, the insulating film 51 is formed on the upper electrode 47. The insulating film 51 is formed of a silicon oxide film or the like, and the film thickness (deposited film thickness) thereof can be approximately 250 to 500 nm. The insulating film 51 is preferably formed at a temperature at which sublimation of the chalcogenide material constituting the solid electrolyte region 46 does not occur, for example, at the temperature of 400° C. or lower. In this manner, the sublimation of the solid electrolyte region 46 when forming the insulating film 51 can be prevented.

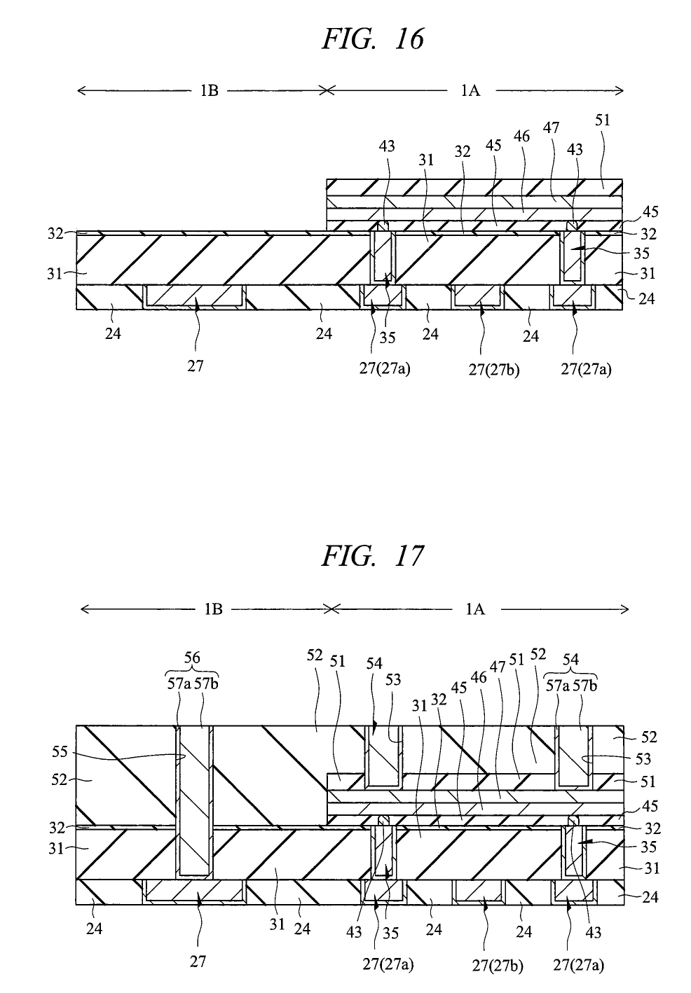

Next, as shown in FIG. 16, a photoresist pattern (not shown) is formed on the insulating film 51 in the memory region 1A by the photolithography method, and the insulating film 51 is dry etched and patterned with using the photoresist pattern as an etching mask. Next, after removing the photoresist pattern, the upper electrode 47, the solid electrolyte region 46 and the second component releasing region 45 made of the first and second components are dry etched and patterned with using the patterned insulating film 51 as a hard mask (etching mask). By this means, the resistor element 48 which is composed of a laminated film of the patterned upper electrode 47, solid electrolyte region 46 and second component releasing region 45 made of the first and second components is formed (processed). Note that, when the upper electrode 47, the solid electrolyte region 46 and the second component releasing region 45 made of the first and second components are dry etched, the film for preventing peeling 32 can be used as an etching stopper film.

Next, as shown in FIG. 17, the insulating film (interlayer insulation film) 52 formed of a silicon oxide film or the like is formed on the film for preventing peeling 32 so as to cover the resistor element 48 and the insulating film 51 adjacent thereto. After forming the insulating film 52, the CMP treatment and others are performed as necessary to planarize the upper surface of the insulating film 52.

Next, the insulating film 52 and the insulating film 51 are dry etched with using a photoresist pattern (not shown) formed on the insulating film 52 by the photolithography method as an etching mask, thereby forming through holes (opening, connection hole, via hole) 53 in the insulating film 52 and the insulating film 51. The through holes 53 are formed in the memory region 1A, and the upper surface of the upper electrode 47 of the resistor element 48 is exposed on the bottom surfaces of the through holes 53. Then, the photoresist pattern is removed.

Next, the insulating film 52, the film for preventing peeling 32, and the insulating film 31 are dry etched with using another photoresist pattern (not shown) formed on the insulating film 52 by the photolithography method as an etching mask, thereby forming the through hole (opening, connection hole, via hole) 55 in the insulating film 52, the film for preventing peeling 32, and the insulating film 31. The through hole 55 is formed in the peripheral circuit region 1B, and the upper surface of the wiring 27 is exposed on the bottom surface of the through hole 55. Then, the photoresist pattern is removed. Note that it is also possible to form the through hole 55 first and then form the through holes 53. Further, the through holes 53 and the through hole 55 are preferably formed in different processes since depths thereof are different, but they can be formed in the same process.

Next, the plugs 54 and 56 are formed in the through holes 53 and 55. In this process, for example, after forming the conductive barrier film 57a by the sputtering process or others on the insulating film 52 including the inside of the through holes 53 and 55, the tungsten film 57b is formed on the conductive barrier film 57a by the CVD method so as to fill the through holes 53 and 55, and the unnecessary part of the tungsten film 57b and the conductive barrier film 57a adjacent to the insulating film 52 is removed by the CMP method or the etch back method. In this manner, the plugs 54 formed of the tungsten film 57b and the conductive barrier film 57a that are left to be embedded in the through holes 53 and the plug 56 formed of the tungsten film 57b and the conductive barrier film 57a that are left to be embedded in the through hole 55 can be formed. It is also possible to use an aluminum (Al) film or an aluminum alloy film (main conductive film) instead of the tungsten film 57b. As described above, the plugs 54 and 56 are formed by filling the openings (through holes 53 and 55) formed in the insulating film with a conductive material.

In the present embodiment, the plugs 54 and 56 are formed in the same process after forming the through holes 53 and 55. Accordingly, the number of manufacturing processes can be reduced. In another embodiment, after forming one of the through hole 53 and the through hole 55, the plug (one of the plug 54 and the plug 56) for filling the through hole is formed, and then, after forming the other one of the through hole 53 and the through hole 55, the plug (the other one of the plug 54 and the plug 56) for filling the through hole is formed.

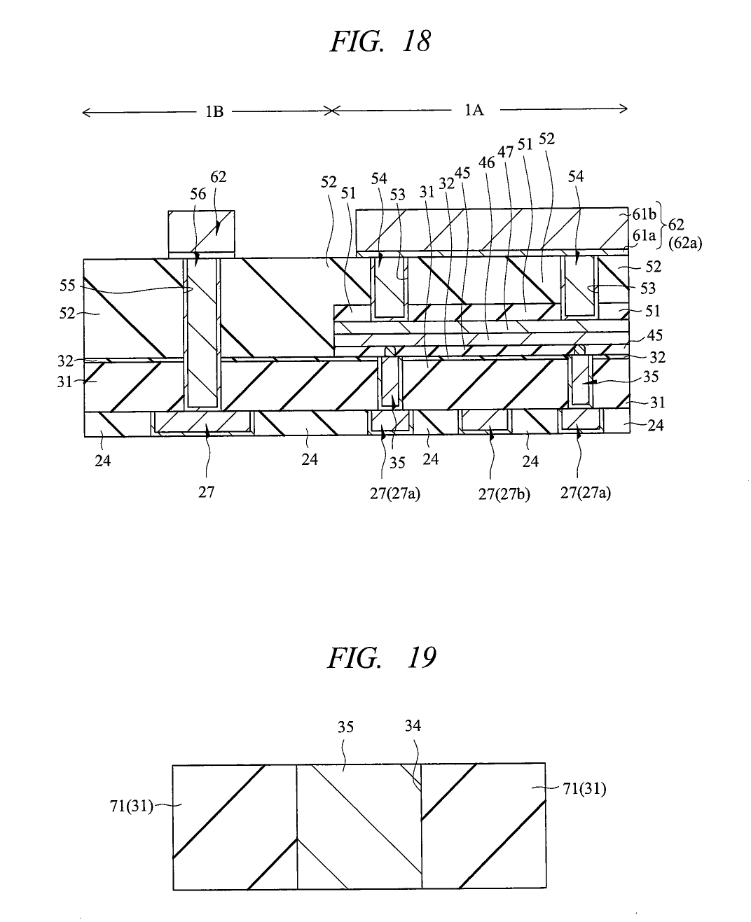

Next, as shown in FIG. 18, the wiring 62 is formed as a second layer interconnection on the insulating film 52 in which the plugs 54 and 56 are embedded. For example, the wiring 62 can be formed by sequentially forming the conductive barrier film 61a and the aluminum film or aluminum alloy film 61b by the sputtering process or the like on the insulating film 52 in which the plugs 54 and 56 are embedded and patterning these films by using the photolithography method, the dry etching method and others. The wiring 62 is not limited to the above-mentioned aluminum wiring, but various modifications are possible. For example, a tungsten wiring or a copper wiring (embedded copper wiring) can be used. In the memory region 1A, the wiring 62 forms the wiring (bit line, bit line wiring) 62a that functions as a bit line.

Thereafter, an insulating film (not shown) as an interlayer insulation film is formed on the insulating film 52 so as to cover the wiring 62, and upper wiring layers (wirings of third and subsequent layer interconnections) are further formed, but the illustrations and descriptions thereof are omitted here. Then, after hydrogen annealing at the temperature of approximately 400° C. to 450° C. is performed, a semiconductor device (semiconductor memory device) is completed.

Next, the process of forming the second component releasing region 45 made of the first and second components will be described in more detail. FIGS. 19 to 25 are sectional views showing the principal part in a process of forming the second component releasing region 45 made of the first and second components in the manufacturing process of the semiconductor device according to the present embodiment, in which the region close to the upper part of the plug 35 in the memory region 1A, that is, the region corresponding to FIG. 4 is shown. Although the insulating film 71 of FIGS. 19 to 25 corresponds to the insulating film 31, the film for preventing peeling 32 is included in the insulating film 71 in the illustration of FIGS. 19 to 25.

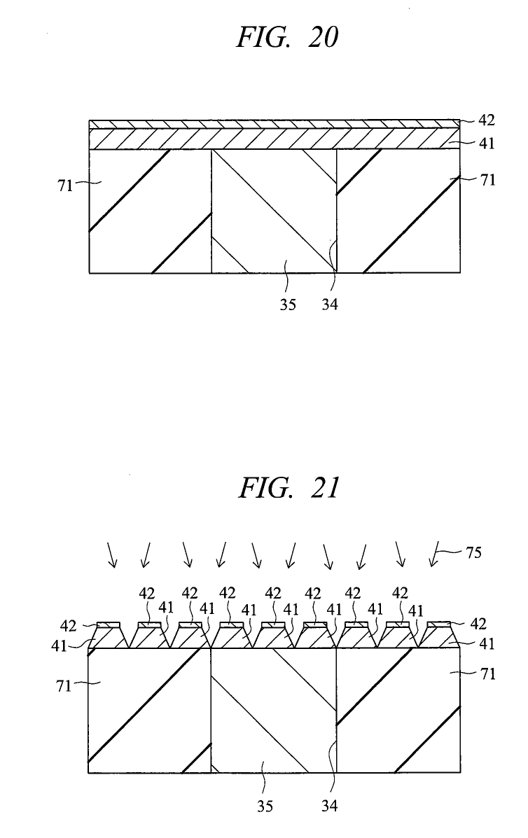

After the structure of FIG. 19 corresponding to FIG. 13 is obtained by performing the processes of FIG. 10 to 13, as shown in FIG. 20, a material film (first material film) 41 for forming the electrode portion 43 is formed (deposited) over the whole surface of the main surface of the semiconductor substrate 1, that is, on the insulating film 71 in which the plug 35 is embedded. Since the electrode portion 43 is formed of the material film 41, the material film 41 needs to contain an element that constitutes the first component (oxide of metal or semiconductor) and an element that constitutes the second component (Cu or Ag). Therefore, the material film 41 is made of a metal element or semiconductor element for forming the first component, an oxygen element for forming the first component, and copper (Cu) or silver (Ag) for forming the second component. For example, the material film 41 can be formed of a Cu₆₀Ta₁₀O₃₀ film (film with the atomic ratio of copper (Cu) of 60 atom %, tantalum (Ta) of 10 atom %, and oxygen (O) of 30 atom %) and can be deposited by the sputtering process or the like. For example, the deposition thickness of the material film 41 can be approximately 30 to 50 nm.

Next, a titanium (Ti) film 42 (mask layer, second material film) is formed on the material film 41. More specifically, the titanium film 42 adjacent to the material film 41 is formed. The titanium film 42 is, as mentioned later, a material film to be used as a mask (etching mask) when etching (sputter etching) the material film 41. The titanium film 42 is formed to have a small deposition thickness of several nm (for example, approximately 5 nm) and can be formed by the sputtering process or others. Accordingly, the deposition thickness of the titanium film 42 is smaller than the deposition thickness of the material film 41. Since the titanium film 42 is thin, it does not form a completely continuous film in a plane, but is locally deposited in a granular form on the material film 41.

Next, etching, preferably sputter etching is performed to the main surface of the semiconductor substrate 1. In this process, it is more preferable to perform sputter etching using Ar (argon) ions. More specifically, etching is performed with a physical bombardment (ion bombardment) using Ar ions. By this means, as shown in FIG. 21, the titanium film 42 and the material film 41 are sputtered and etched. In FIG. 21, sputter etching, that is, Ar ions flying to the laminated film of the material film 41 and the titanium film 42 is schematically illustrated with arrows 75.

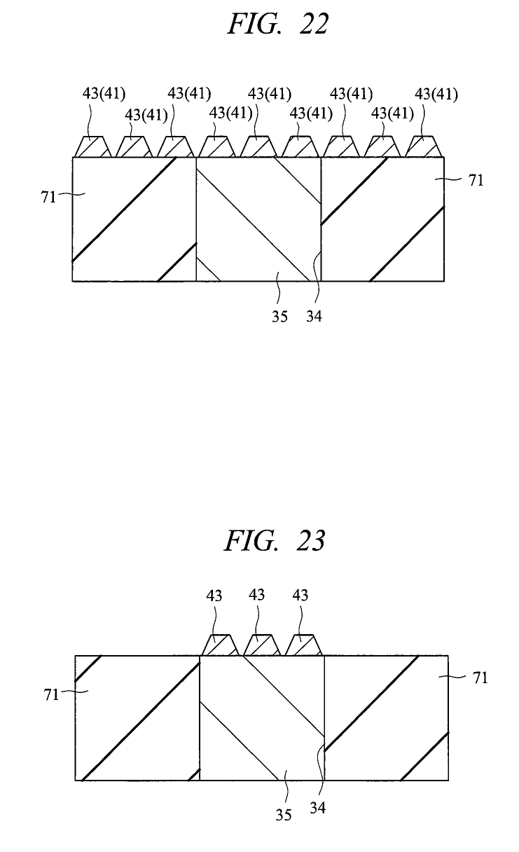

In this sputter etching process, since the titanium film 42 does not easily scatter even with the ion bombardment of Ar (not easily sputtered, not easily etched, not easily sputter etched), the granular titanium film 42 functions as a mask (etching mask, sputter etching mask). The function as a mask continues until the titanium film 42 is removed by sputter etching. On the other hand, the material film 41 easily scatters with the ion bombardment of Ar compared to the titanium film 42 (easily sputtered, easily etched, easily sputter etched). Therefore, as shown in FIG. 21, the material film 41 is removed by sputter etching in the region not covered with the granular titanium film 42, and the material film 41 remains owing to the function of the titanium film 42 as a mask in the region covered with the granular titanium film 42. Then, although sputter etching is continued for a while even after the titanium film 42 is removed, sputter etching is finished before the material film 41 is completely removed. In this manner, as shown in FIG. 22, the material film 41 is divided into a plurality of dome-shaped electrode portions 43, and a part of the material film 41 other than the part used as the electrode portions 43 is removed.

Further, even if the granular titanium films 42 are connected with each other when the titanium film 42 is deposited on the material film 41, since the titanium film 42 is thin in grain boundaries if the deposition thickness of the titanium film 42 is sufficiently small, the titanium film 42 is etched from the grain boundaries in the sputter etching of Ar ions to form the granular titanium films 42, and the granular titanium films 42 function as a mask. Therefore, sputter etching proceeds as shown in FIG. 21 to 22, and the material film 41 is divided into the plurality of dome-shaped (semicircular) electrode portions 43.

Also, even if the material film 41 is partially removed by sputter etching and the upper surface of the underlying plug 35 is exposed, since the tungsten film 35b constituting the plug 35 does not easily scatter even with the ion bombardment of Ar (not easily sputter etched), it is possible to suppress or prevent the upper surface of the plug 35 from being sputter etched.

As described above, by the etching (sputter etching) using the titanium film 42 as a mask, the material film 41 can be divided into the plurality of dome-shaped electrode portions 43. At least one of the plurality of electrode portions 43 formed by dividing the material film 41, that is, the electrode portion 43 located on the plug 35 functions as an electrode (electrode to supply the metal element 73 to the solid electrolyte region 46) of the storage element as mentioned above.

Next, as shown in FIG. 23, the electrode portions 43 not located on the plug 35 are removed and the electrode portions 43 adjacent to the plug 35 are left with using the photoresist pattern (not shown) formed over the semiconductor substrate 1 by the photolithography method as an etching mask. Then, the photoresist pattern is removed.

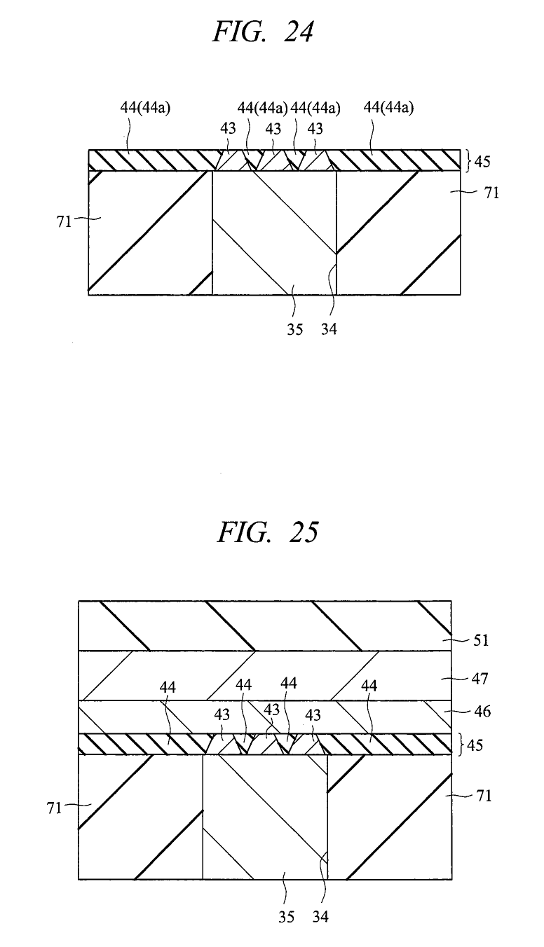

Next, as shown in FIG. 24, an insulating film 44a formed of a silicon oxide film or an aluminum oxide film is formed over the main surface of the semiconductor substrate 1 by the sputtering process or the like so as to fill the gaps between the electrode portions 43 and cover the electrode portions 43, and the part of the insulating film 44a adjacent to the electrode portion 43 is removed by the CMP method, etching (sputter etching) or the like, thereby exposing the top part (upper part, upper surface) of the electrode portion 43. In this process, the insulating film 44a is left around the electrode portions 43, and the insulating film 44 is formed from the remaining insulating film 44a. In this manner, the top part of the electrode portion 43 is exposed from the insulating film 44, and the insulating film 44 is left between and around the electrode portions 43, so that the second component releasing region 45 made of the first and second components composed of the insulating film 44 in which the electrode portions 43 are embedded is formed.

When the insulating film 44a adjacent to the electrode portion 43 is removed by the CMP method, the insulating film 44 is simply polished until the top part of the electrode portion 43 is exposed. Also, when depositing the insulating film 44a, the insulating film 44a on the electrode portion 43 is formed into a projected shape in reflection of the shape of the underlying electrode portion 43. Therefore, when the insulating film 44a adjacent to the electrode portion 43 is removed by sputter etching, the insulating film 44a on the electrode portion 43 is selectively etched by the use of the property that the projected portion of the insulating film 44a can be easily etched by the electric field concentration of sputter etching, thereby exposing the top part of the electrode portion 43 from the insulating film 44.

Thereafter, the processes shown in FIG. 15 to 18 are performed. More specifically, as shown in FIG. 25 corresponding to the process step of FIG. 15, the solid electrolyte region 46, the upper electrode 47 and the insulating film 51 are sequentially formed on the second component releasing region 45 made of the first and second components (that is, on the electrode portion 43 and the insulating film 44). By this means, the solid electrolyte region 46 adjacent to the second component releasing region 45 (the electrode portion 43 and the insulating film 44) is formed, and the upper electrode 47 adjacent to the solid electrolyte region 46 is formed. As mentioned above, the solid electrolyte region 46 is a layer containing chalcogenide or oxide as a main component, and is more preferably a chalcogenide layer. For example, the solid electrolyte region 46 can be formed of a Cu₁₀Mo₃₀S₆₀ film, a Cu₁₀Mo₃₅S₅₅ film, a Cu₁₀Ta₃₀S₆₀ film or an Ag₁₀Mo₃₀S₆₀ film. The Cu₁₀Mo₃₀S₆₀ film is a film with an atomic ratio of copper (Cu) of 10 atom %, molybdenum (Mo) of 30 atom %, and sulfur (S) of 60 atom %, and the Cu₁₀Mo₃₅S₅₅ film is a film with an atomic ratio of copper (Cu) of 10 atom %, molybdenum (Mo) of 35 atom %, and sulfur (S) of 55 atom %. Further, the Cu₁₀Ta₃₀S₆₀ film is a film with an atomic ratio of copper (Cu) of 10 atom %, tungsten (Ta) of 30 atom %, and sulfur (S) of 60 atom %, and the Ag₁₀Mo₃₀S₆₀ film is a film with an atomic ratio of silver (Ag) of 10 atom %, molybdenum (Mo) of 30 atom %, and sulfur (S) of 60 atom %. The solid electrolyte region 46 can be formed by the sputtering process or the like. The upper electrode 43 is formed of a conductor film (metal film) such as a tungsten (W) film, and can be formed by the sputtering process or the like.

Also, although the material film 41 is amorphous at the time of deposition, the material film 41 and the electrode portion 43 formed of the metal film 41 are crystallized due to various heating processes in the manufacturing process of the semiconductor device after the deposition of the material film 41. Accordingly, as shown in FIG. 5, the first portions 43a made of the first component (for example, tantalum oxide) in the electrode portion 43 become microscopic particles or microcrystals of the first component (for example, tantalum oxide), and the second portions 43b made of the second component (copper or silver) exist in the gaps between the first portions 43a.

In addition, it is also possible to leave the electrode portions 43 in the region not located on the plug 35 by omitting the etching process of FIG. 23. In this case, the electrode portions 43 exist not only on the plug 35 but in the whole surface of the second component releasing region 45 made of the first and second components, and the structure as shown in FIG. 7 can be obtained.

By the structure and the manufacturing method according to the present embodiment, a drive voltage and drive current can be lowered in the semiconductor device that can store information. In addition, the number of rewritable times can be increased. Also, a high-speed setting can be achieved. Further, the reproducibility can be improved with a low manufacturing cost. Therefore, the performance of the semiconductor device that can store information can be improved.

In addition, in the present embodiment, although the electrode portion 43 which is a plug-shaped electrode is formed on the side closer to the transistor than the solid electrolyte region 46, that is, between the solid electrolyte region 46 and the MISFETs QM1 and QM2. Alternatively, in another embodiment, the electrode portion 43 which is a plug-shaped electrode can be formed on the side farther from the transistor than the solid electrolyte region 46, that is, between the solid electrolyte region 46 and the plugs 54. In this case, the second component releasing region 45 made of the first and second components and the upper electrode 47 are interchanged, and the upper electrode 47, the solid electrolyte region 46, and the second component releasing region 45 made of the first and second components are sequentially formed between the plugs 35 connected to the MISFETs QM1 and QM2 and the plug 54 connected to the upper wiring 62a from the bottom (from the side close to the plug 35). However, the case where the electrode portion 43 which is a plug-shaped electrode is formed on the side closer to the transistor than the solid electrolyte region 46 (between the solid electrolyte region 46 and the MISFETs QM1 and QM2) as shown in the present embodiment is more preferable because the current for resetting can be reduced approximately by 30%. In addition, in the case where the electrode portion 43 which is a plug-shaped electrode is formed on the side closer to the transistor than the solid electrolyte region 46 as shown in the present embodiment, the formation of the second component releasing region 45 made of the first and second components including the electrode portion 43 which is a plug-shaped electrode can be facilitated.

In the present embodiment, although the ion plug memory having a memory cell composed of one storage element (solid electrolyte region 46) made of a chalcogenide material and one transistor (MISFET QM1 or QM2) has been mainly described, the configuration of the memory cell is not limited thereto. The storage element according to the present embodiment can be rewritten more than one million times, and can be manufactured with a high yield. Further, the advantage of further increasing the number of rewritable times can be achieved by forming a barrier film made of nitride of transition metal such as TiAlN or oxide such as Cr—O so as to be adjacent to the solid electrolyte region 46 of chalcogenide, by using a chalcogenide series material with the Zn or Cd content of 10 atom % or higher and with a melting point of 1000° C. or higher as a material of the solid electrolyte region 46, or by using an alloy film of titanium and tungsten (for example, W80Ti20 (an alloy of tungsten of 80 atom % and titanium of 20 atom %)) or a laminated film of the alloy film and a tungsten film as the upper electrode 47. Alternatively, for the purpose of suppressing the diffusion of heat, a conductive film with poor thermal conductivity such as ITO (mixture of oxide of indium and tin) can also be inserted between the chalcogenide (solid electrolyte region 46) and the upper electrode 47. Also, when a material such as a Zn—Te series material is used instead of TiAlN for a heating material on the lower contact (plug 35), Joule heating from this part can provide auxiliary heating for the lower part of the solid electrolyte region 46, and the approximately 30% reduction of the reset current and improved writing characteristics can be achieved compared to the case of the W contact.

### Second Embodiment

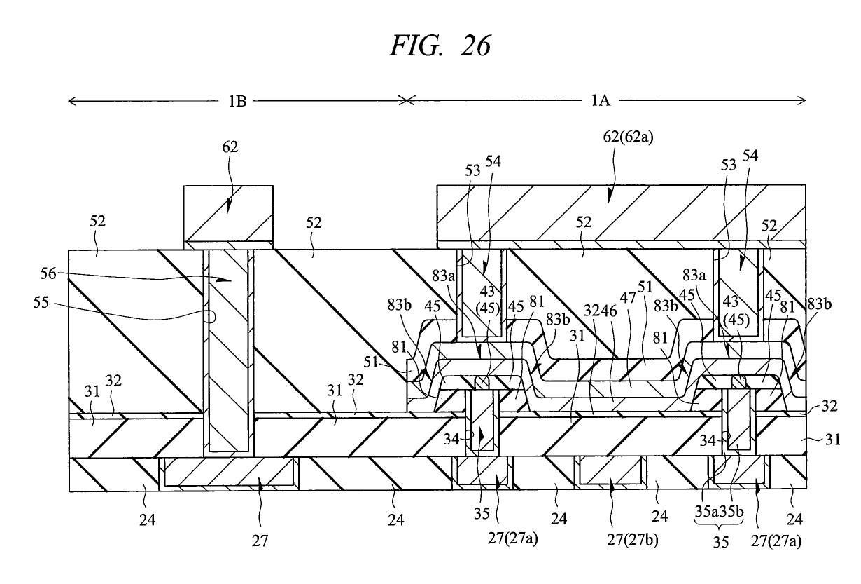

FIG. 26 is a sectional view showing the principal part of the semiconductor device according to the present embodiment. FIG. 26 corresponds to FIG. 3 of the first embodiment. Since the insulating film 21 and the structure below it of FIG. 26 are the same as those of the first embodiment described above (FIG. 3), the illustration thereof is omitted for the sake of making the drawings easy to see.

In the first embodiment, the laminated film of the solid electrolyte region 46 and the upper electrode (the upper electrode region) 47 is formed almost evenly. In the present embodiment, concavities and convexities are provided to the laminated film of the solid electrolyte region 46 and the upper electrode 47.

The insulating film 31 is formed on the insulating film 24 in which the wirings 27 are embedded, and the film for preventing peeling 32 is formed on the insulating film 31. In the present embodiment, as shown in FIG. 26, an insulating film (interlayer insulation film) 81 formed of a silicon oxide film or the like is formed on the film for preventing peeling 32 in the memory region 1A. In the present embodiment, the through holes 34 are formed through the insulating film 31, the film for preventing peeling 32 and the insulating film 81 in the memory region 1A, and the plugs 35 are formed in the through holes 34. The insulating film 81 in the memory cell region 1A is more preferably separated by patterning for each memory cell bit as shown in FIG. 3. Therefore, the insulating film 81 is formed only around the plugs 35.

The second component releasing region 45 made of the first and second components is formed on the upper surface of the plug 35 and on the upper surface of the insulating film 81 in the memory region 1A. Similar to the first embodiment, at least one electrode portion 43 exists on the plug 35. The solid electrolyte region 46 is formed on the film for preventing peeling 32 including the second component releasing region 45 made of the first and second components, the upper electrode 47 is formed on the solid electrolyte region 46, and the insulating film 51 is formed on the upper electrode 47. The plug 54 connecting the wiring 62 and the upper electrode 47 is formed on the flat region of the upper electrode 47.

Other configurations are almost the same as those of the first embodiment, and descriptions thereof are omitted here.

In the present embodiment, a convex portion composed of the upper part of the plug 35 and the insulating film 81 is formed on the laminated film of the insulating film 31 and the film for preventing peeling 32 by locally providing the insulating film 81 around the plug 35, the second component releasing region 45 made of the first and second components is formed on the convex portion, and the solid electrolyte region 46 and the upper electrode 47 are formed so as to cover the convex portion (corresponding to a convex portion 82 described later) including the second component releasing region 45 made of the first and second components. Therefore, the solid electrolyte region 46 and the upper electrode 47 have a flat region (flattened region, first region) 83a located on the convex portion (82) and an inclined region (slanted region, stepped section, second region) 83b tilted relative to the flat region 83a around the flat region 83a. The top of the plug 35 is the flat region 83a, and the solid electrolyte region 46 and the electrode portion 43 adjacent to the plug 35 are in contact (adjacent, facing) in the flat region 83a. The region 83b is a step-shaped region tilted in accordance with the step (sidewall) of the convex portion (82). In the region 83b, the thickness of the solid electrolyte region 46 and the upper electrode 47 is smaller than those in the flat region 83a.

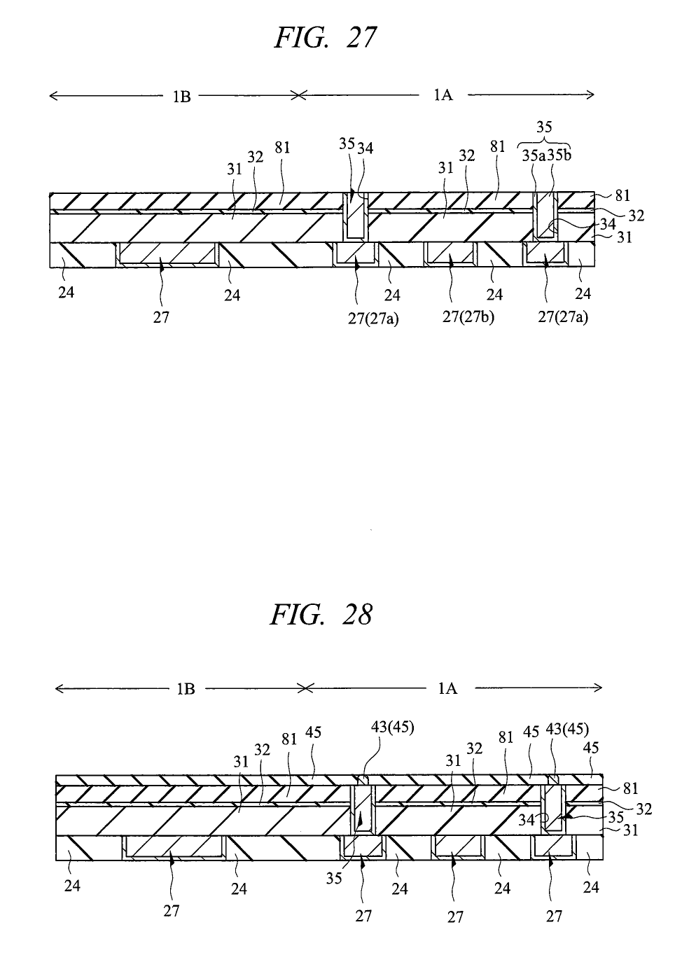

Next, the manufacturing process of the semiconductor device according to the present embodiment will be described with reference to the accompanying drawings. FIGS. 27 to 32 are sectional views showing the principal part of the semiconductor device during a manufacturing process according to the present embodiment. Since the manufacturing process up to FIG. 12 is the same as that of the first embodiment, descriptions thereof are omitted, and the manufacturing process subsequent to FIG. 12 will be described. FIGS. 27 to 32 show the areas corresponding to FIG. 26, and the illustration of the part corresponding to the insulating film 21 and the structure below it is omitted in the same manner as FIG. 26 for the sake of simplification.

After the structure shown in FIG. 12 is formed in the same manner as the first embodiment, the insulating film 31 and the film for preventing peeling 32 are sequentially formed on the insulating film 24 in which the wirings 27 are embedded, and the insulating film 81 is further formed on the film for preventing peeling 32 as shown in FIG. 27. The thickness of the insulating film 81 is larger than the thickness of the film for preventing peeling 32, and the insulating film 81 can be formed of a silicon oxide film or the like.

Next, the insulating film 81, the film for preventing peeling 32, and the insulating film 31 are dry etched with using a photoresist pattern (not shown) formed on the insulating film 81 by the photolithography method as an etching mask, thereby forming the through holes 34 in the insulating film 81, the film for preventing peeling 32, and the insulating film 31. The through holes 34 are formed in the memory region 1A, and the upper surfaces of the wirings 27a are exposed on the bottom surfaces of the through holes 34. Then, the plugs 35 are formed in the through holes 34 in the same manner as the first embodiment.

Next, as shown in FIG. 28, the second component releasing region 45 made of the first and second components is formed on the insulating film 81 so as to cover the plugs 35. Since the process of forming the second component releasing region 45 made of the first and second components is the same as that of the first embodiment, descriptions thereof are omitted here.

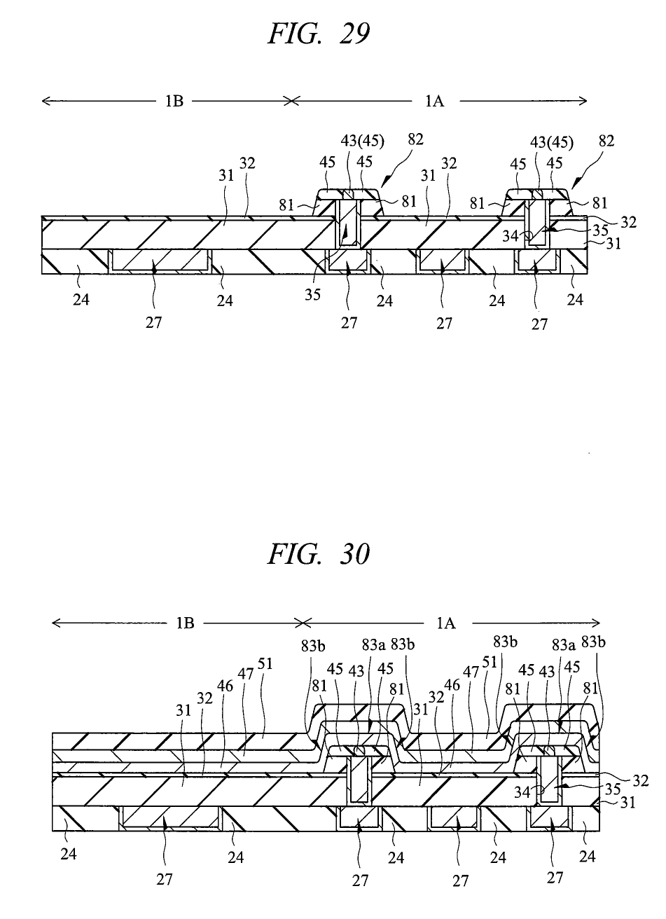

Next, as shown in FIG. 29, the second component releasing region 45 made of the first and second components and the insulating film 81 are dry etched with using a photoresist pattern (not shown) formed on the second component releasing region 45 made of the first and second components by the photolithography method as an etching mask. In this process, the film for preventing peeling 32 can function as an etching stopper film. In this dry etching process, by using the photoresist pattern that planarly includes the plug 35 and has a slightly larger area than the upper surface of the plug 35, the insulating film 81 and the second component releasing region 45 made of the first and second components on the plug 35 and around (in the vicinity of) the plug 35 are left, and the second component releasing region 45 made of the first and second components and the insulating films 81 in the other region are removed. By this means, the insulating film 81 locally remains around the plug 35, and the insulating film 81 is removed in the region other than the vicinity of the plug 35, so that the upper surface drops down to expose the film for preventing peeling 32. Consequently, the convex portion 82 composed of the upper part of the plug 35, the insulating film 81 around the plug 35, and the second component releasing region 45 made of the first and second components adjacent to the upper surface of the plug 35 and the insulating film 81 is formed.

Next, as shown in FIG. 30, the solid electrolyte region 46, the upper electrode 47, and the insulating film 51 are sequentially formed so as to cover the convex portion 82 over the main surface of the semiconductor substrate 1 (that is, on the film for preventing peeling 32). The process of forming the solid electrolyte region 46, the upper electrode 47, and the insulating film 51 is the same as that of the first embodiment, and descriptions thereof are omitted here.

When the solid electrolyte region 46 and the upper electrode 47 are formed so as to cover the convex portion 82, the solid electrolyte region 46 and the upper electrode 47 are formed to be almost conformal in reflection of the shape of the underlying convex portion 82. Therefore, the solid electrolyte region 46 and the upper electrode (upper electrode region) 47 include the flat region 83a located on the convex portion 82 and the inclined region 83b around the flat region 83a. However, when the film is formed so as to cover the convex portion 82, the thickness of the film deposited on the sidewall of the convex portion 82 tends to be smaller than the thickness of the film deposited on the flat region. Therefore, the film thickness of the solid electrolyte region 46 and the upper electrode 47 in the inclined region 83b deposited on the sidewall of the convex portion 82 is smaller than the film thickness of the solid electrolyte region (solid electrolyte layer) 46 and the upper electrode 47 in the flat region 83a.

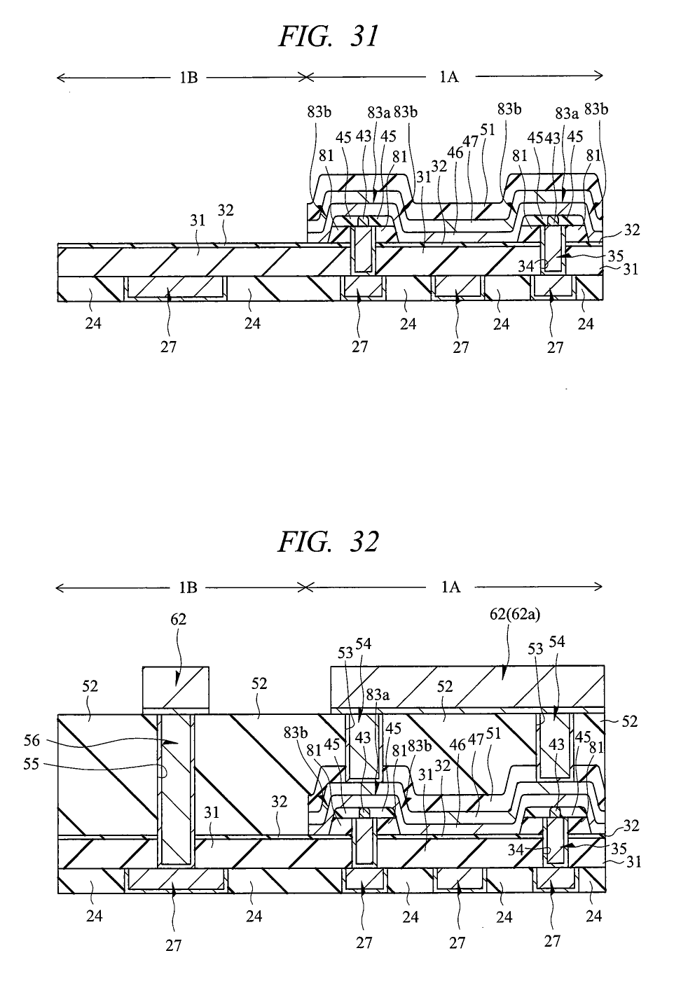

Next, as shown in FIG. 31, the insulating film 51 is dry etched and patterned with using a photoresist pattern (not shown) formed on the insulating film 51 by the photolithography method as an etching mask. Then, after removing the photoresist pattern, the upper electrode 47 and the solid electrolyte region 46 are dry etched and patterned with using the patterned insulating film 51 as a hard mask (etching mask). In this process, the film for preventing peeling 32 can be used as an etching stopper film.

The subsequent processes are almost the same as those of the first embodiment. More specifically, as shown in FIG. 32, after forming the insulating film 52, through holes 53 and 55 are formed, the plugs 54 and 56 are formed in the through holes 53 and 55, and then the wiring 62 is formed on the insulating film 52 in which the plugs 54 and 56 are embedded in the same manner as the first embodiment.

Also in the present embodiment, almost the same effect as the first embodiment can be obtained. In the present embodiment, the inclined region 83b is additionally formed in the solid electrolyte region 46 and the upper electrode 47. Since the film thickness of the solid electrolyte region 46 and the upper electrode 47 in the inclined region 83b is smaller than that in the flat region 83a and the arrangement of crystal grains tends to be disturbed in the inclined region 83b, the amount of thermal diffusion in the plane of the solid electrolyte region 46 and the upper electrode 47 decreases, and thus an effect of making the temperature rise easy by means of the thermal insulation and an effect of preventing the excessive spread of a dissolution region can be achieved. More specifically, the diffusion of heat and current from the flat region 83a through the inclined region 83b can be suppressed or prevented. By this means, the drive voltage can be further decreased. It is more preferable when the film thickness of the solid electrolyte region 46 and the upper electrode 47 in the inclined region 83b is in the range of 20% to 80% of the film thickness of the solid electrolyte region 46 and the upper electrode 47 in the flat region 83a, and the electric power reduction effect becomes conspicuous, and for example, the low voltage operation of approximately 2.2 V can be achieved. In addition, it is more preferable that the lower surface of the solid electrolyte region 46 of the flat region 83a located on the convex portion 82 is located at a position higher than the average upper surface of the solid electrolyte region 46 in the region apart from the convex portion 82 beyond the inclined region 83b. By this means, the above-mentioned effect by the convex portion can always be obtained regardless of the film thickness of the solid electrolyte region 46. In this case, the drive voltage can be further decreased, for example, approximately to 1.8 V.

### Third Embodiment

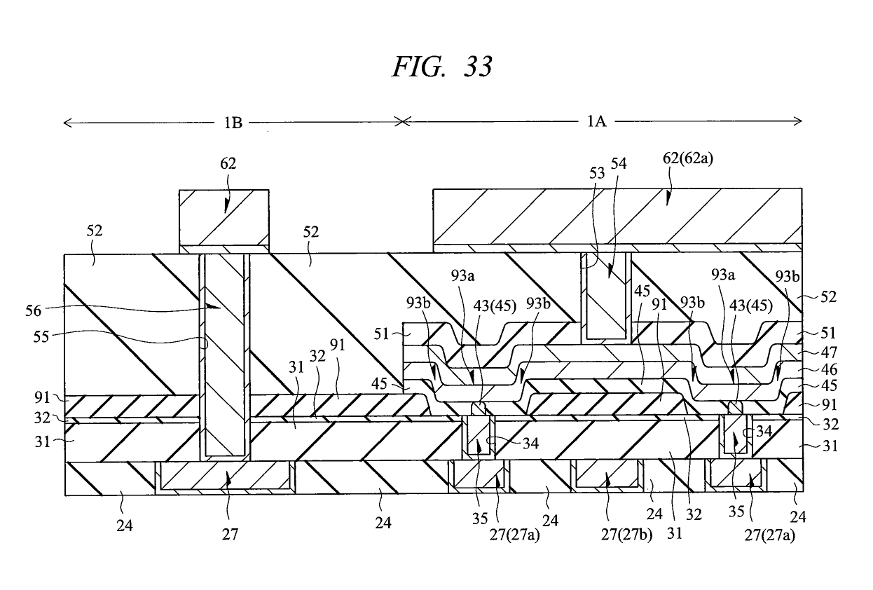

FIG. 33 is a sectional view showing the principal part of the semiconductor device according to the present embodiment. FIG. 33 corresponds to FIG. 3 of the first embodiment described above. Since the insulating film 21 and the structure below it are the same as those of the first embodiment (FIG. 3), the illustration thereof is omitted for the sake of making the drawing easy to see.

In the first embodiment, the laminated film of the solid electrolyte region 46 and the upper electrode 47 is formed almost evenly. In the present embodiment, concavities and convexities are provided to the laminated film of the solid electrolyte region 46 and the upper electrode layer 47.

In the present embodiment, as shown in FIG. 33, an insulating film 91 formed of a silicon oxide film or the like is formed on the laminated film of the insulating film 31 in which the plugs 35 are embedded and the film for preventing peeling 32 in the memory region 1A. The insulating film 91 is not formed on the plugs 35 and in the vicinity thereof, but is formed around them. It does not matter if the insulating film 91 is formed in the peripheral circuit region 1B or not.

The second component releasing region 45 made of the first and second components is formed on the upper surface of the plug 35 and on the upper surface of the insulating film 91 in the memory region 1A. Similar to the first embodiment, at least one electrode portion 43 exists on the plug 35. The solid electrolyte region 46 is formed on the second component releasing region 45 made of the first and second components, the upper electrode 47 is formed on the solid electrolyte region 46, and the insulating film 51 is formed on the upper electrode 47. The plug 54 connecting the wiring 62 and the upper electrode 47 is formed on the flat region of the upper electrode 47.

Other configurations are almost the same as those of the first embodiment, and descriptions thereof are omitted here.

In the present embodiment, the insulating film 91 is formed on the film for preventing peeling 32 in the regions other than on the plug 35 and in the vicinity thereof. By this means, a concave portion (corresponding to a concave portion 92 described later) is formed from the opening in the insulating film 91, and then the second component releasing region 45 made of the first and second components, the solid electrolyte region 46, and the upper electrode 47 are formed so as to cover the concave portion. Therefore, the solid electrolyte region 46 and the upper electrode 47 have a flat region (a flattened region, a first region) 93a located at the bottom of the concave portion (92) and an inclined region (slanted region, stepped section, second region) 93b tilted relative to the flat region 93a around the flat region 93a. Since the plug 35 is located at the bottom of the concave portion (92), the top of the plug 35 is the flat region 93a, and the solid electrolyte region 46 and the electrode portion 43 adjacent to the plug 35 are in contact (adjacent, facing) in the flat region 93a. The region 93b is a step-shaped region titled in accordance with the step (inner wall) of the concave portion (92). The film thickness of the solid electrolyte region 46 and the upper electrode 47 in the region 93b is smaller than that in the flat region 93a.

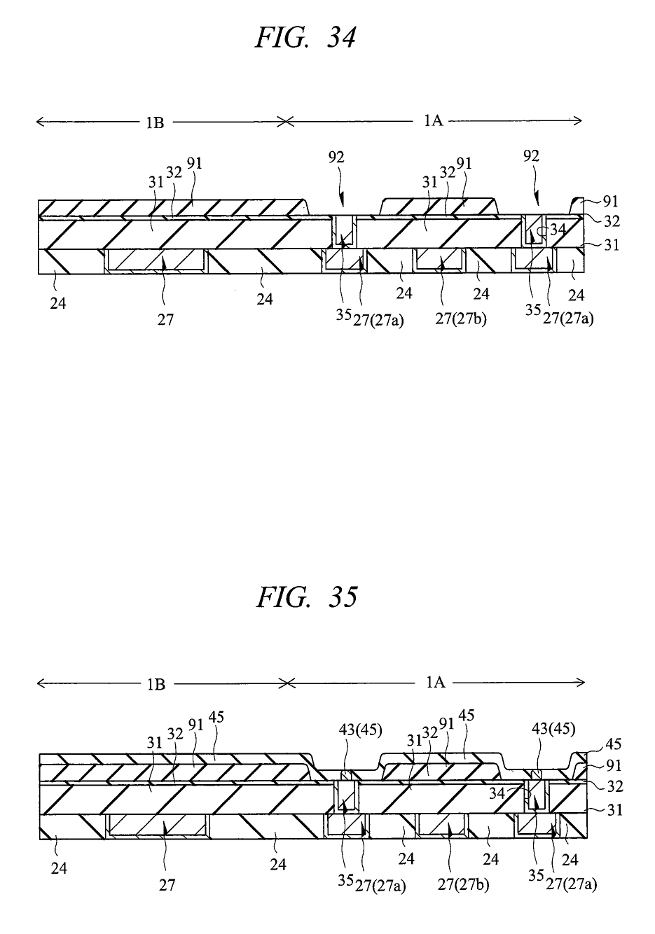

Next, the manufacturing process of the semiconductor device according to the present embodiment will be described with reference to the accompanying drawings. FIGS. 34 to 38 are sectional views showing the principal part of the semiconductor device during a manufacturing process according to the present embodiment. Since the manufacturing process up to FIG. 13 is the same as that of the first embodiment, descriptions thereof are omitted, and the manufacturing process subsequent to FIG. 13 will be described. FIGS. 34 to 38 show the areas corresponding to FIG. 33, and the illustration of the part corresponding to the insulating film 21 and the structure below it is omitted in the same manner as FIG. 33 for the sake of easy understanding.

After the structure shown in FIG. 13 is formed in the same manner as the first embodiment, the insulating film 91 is formed on the laminated film of the insulating film 31 in which the plugs 35 are embedded and the film for preventing peeling 32 as shown in FIG. 34. Then, the insulating film 91 is dry etched with using a photoresist pattern (not shown) formed on the insulating film 91 by the photolithography method as an etching mask. In this process, the film for preventing peeling 32 can function as an etching stopper film. In this dry etching process, by forming the photoresist pattern so that the photoresist pattern has an opening and the opening planarly includes the plug 35 and has a slightly larger area than the upper surface of the plug 35, the insulating film 91 on the plug 35 and around (in the vicinity of) the plug 35 is removed, and the insulating film 91 in the other region is left. By this means, the insulating film 91 is locally removed on and around the plug 35, and the concave portion (opening) 92 is formed from the opening of the insulating film 91. At the bottom of the concave portion (opening) 92, the plug 35 and/or the film for preventing peeling 32 are exposed.

Next, as shown in FIG. 35, the second component releasing region 45 made of the first and second components is formed on the insulating film 91 including the bottom of the concave portion 92. Although the process of forming the second component releasing region 45 made of the first and second components is the same as that of the first embodiment, since the top part of the electrode portion 43 has to be exposed at the bottom of the concave portion 92, sputter etching is preferably used instead of CMP to remove the insulating film 44a adjacent to the electrode portion 43 in the process of FIG. 24.

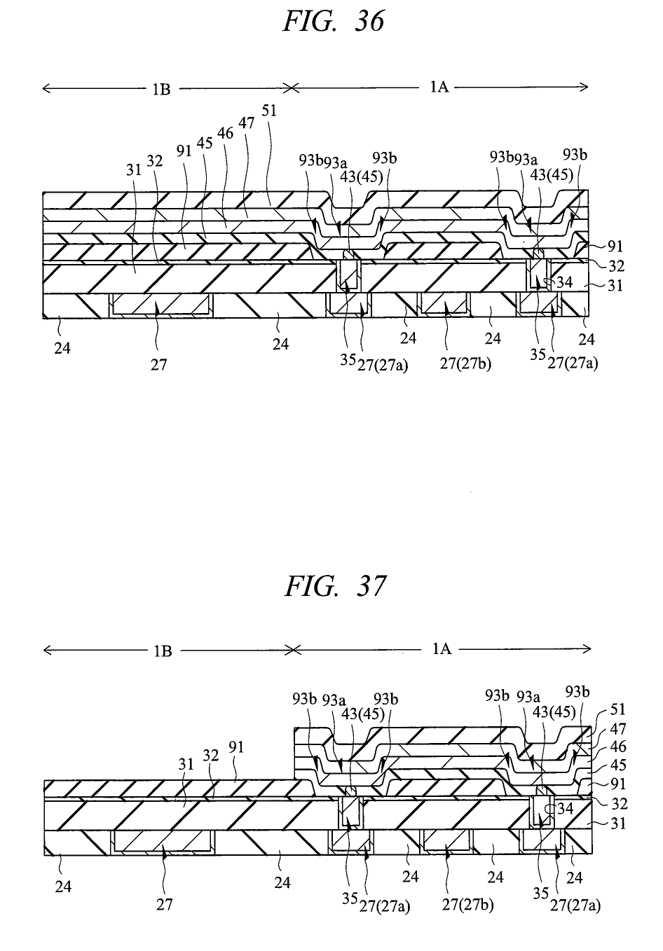

Next, as shown in FIG. 36, the solid electrolyte region 46, the upper electrode 47, and the insulating film 51 are sequentially formed over the main surface of the semiconductor substrate 1 (that is, on the second component releasing region 45 made of the first and second components). Since the process of forming the solid electrolyte region 46, the upper electrode 47, and the insulating film 51 is the same as that of the first embodiment, descriptions thereof are omitted here.

Since the solid electrolyte region 46 and the upper electrode 47 are formed so as to cover the concave portion 92, the solid electrolyte region 46 and the upper electrode 47 are formed to be almost conformal in reflection of the shape of the underlying concave portion 92. Therefore, the solid electrolyte region 46 and the upper electrode 47 include the flat region 93a located at the bottom of the concave portion 92 and the inclined region 93b tilted around the flat region 93a. However, when the film is formed so as to cover the concave portion 92, the thickness of the film deposited on the inner sidewall of the concave portion 92 tends to be smaller than the thickness of the film deposited on the flat region. Therefore, the film thickness of the solid electrolyte region 46 and the upper electrode 47 in the inclined region 93b deposited on the inner sidewall of the concave portion 92 is smaller than the film thickness of the solid electrolyte region 46 and the upper electrode 47 in the flat region 93a.

Next, as shown in FIG. 37, the insulating film 51 is dry etched and patterned with using a photoresist pattern (not shown) formed on the insulating film 51 by the photolithography method as an etching mask. Then, after removing the photoresist pattern, the upper electrode 47 and the solid electrolyte region 46 are dry etched and patterned with using the patterned insulating film 51 as a hard mask (etching mask). In this process, the film for preventing peeling 32 can be used as an etching stopper film.

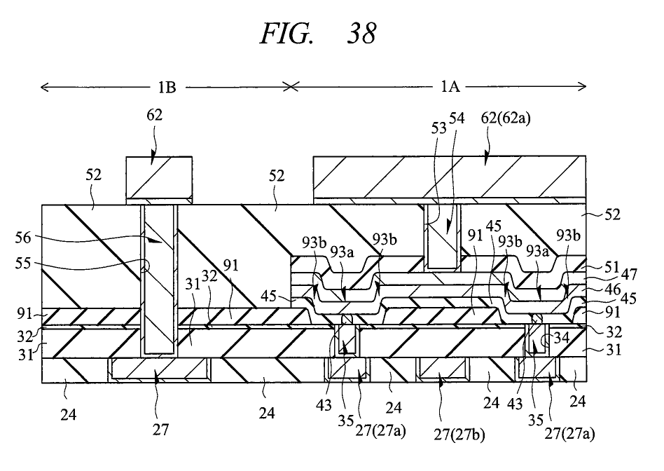

The subsequent processes are almost the same as those of the first embodiment. More specifically, as shown in FIG. 38, after forming the insulating film 52, through holes 53 and 55 are formed, the plugs 54 and 56 are formed in the through holes 53 and 55, and then the wiring 62 is formed on the insulating film 52 in which the plugs 54 and 56 are embedded in the same manner as the first embodiment.

In the present embodiment, almost the same effect as the first embodiment can be obtained. Further, almost the same effect as the second embodiment can also be obtained in the present embodiment. More specifically, in the present embodiment, the inclined region 93b is additionally formed in the solid electrolyte region 46 and the upper electrode 47. Since the film thickness of the solid electrolyte region 46 and the upper electrode 47 in the inclined region 93b is smaller than that in the flat region 93a and the arrangement of crystal grains tends to be disturbed in the inclined region 93b, the amount of thermal diffusion in the plane of the solid electrolyte region 46 and the upper electrode 47 decreases, and thus an effect of making the temperature rise easy by means of the thermal insulation and an effect of preventing the excessive spread of a dissolution region can be achieved. More specifically, the diffusion of heat and current from the flat region 93a through the inclined region 93b can be suppressed or prevented. By this means, the drive voltage can be further decreased. It is more preferable when the film thickness of the solid electrolyte region 46 and the upper electrode 47 in the inclined region 93b is in the range of 20% to 80% of the film thickness of the solid electrolyte region 46 and the upper electrode 47 in the flat region 93a, and the electric power reduction effect becomes conspicuous, and for example, the low voltage operation of approximately 2.2 V can be achieved. In addition, it is more preferable that the upper surface of the solid electrolyte region 46 of the flat region 93a located at the bottom of the concave portion 92 is located at a position lower than the average lower surface of the solid electrolyte region 46 in the region adjacent to the insulating film 91. By this means, the above-mentioned effect by the concave portion can always be obtained regardless of the film thickness of the solid electrolyte region 46. In this case, the drive voltage can be further decreased, for example, approximately to 1.8 V.

In the foregoing, the invention made by the inventors of the present invention has been concretely described based on the embodiments. However, it is needless to say that the present invention is not limited to the foregoing embodiments and various modifications and alterations can be made within the scope of the present invention.

### INDUSTRIAL APPLICABILITY

The present invention is suitably applied to, for example, a semiconductor device having a nonvolatile storage element and a manufacturing method of the same.

1. A semiconductor device comprising:
a second component releasing cell made of a first component and a second component; and
a solid electrolyte region adjacent to the second component releasing cell,
wherein the second component supplied from the second component releasing cell moves inside the solid electrolyte region to change physical characteristics, thereby storing information.

2. The semiconductor device according to claim 1,
wherein the first component is a compound of metal or semiconductor and at least one element selected from a group including oxygen, sulfur, selenium, tellurium, nitrogen, and carbon.

3. The semiconductor device according to claim 1,
wherein a main component of the first component is tantalum oxide.

4. The semiconductor device according to claim 1,
wherein the second component is a metal or metalloid element.

5. The semiconductor device according to claim 1,
wherein the second component is copper or silver.

6. The semiconductor device according to claim 1,
wherein the second component releasing cell comprises first portions made of the first component and second portions made of the second component.

7. The semiconductor device according to claim 6,
wherein the second portion exists in a gap between the first portions in the second component releasing cell.

8. The semiconductor device according to claim 6,
wherein the second component exists in a state of metal in the second portion.

9. The semiconductor device according to claim 2,
wherein a binding force of metal or semiconductor with at least one element selected from the group including oxygen, sulfur, selenium, tellurium, nitrogen and carbon in the first component is greater than a binding force with at least one element selected from the group including oxygen, sulfur selenium, tellurium, nitrogen and carbon in the second component.

10. The semiconductor device according to claim 1,
wherein a melting point of the first component is higher than a melting point of the second component.

11. The semiconductor device according to claim 1,
wherein a proportion of the second component in the second component releasing cell is 30 atom % or higher and 70 atom % or lower.

12. The semiconductor device according to claim 1,
wherein the solid electrolyte region contains chalcogenide, oxide or an organic substance as a main component.

13. The semiconductor device according to claim 1,
wherein the solid electrolyte region is made of chalcogenide, and
the chalcogenide contains at least one element selected from a group including tantalum, molybdenum and titanium, and a chalcogen element.

14. The semiconductor device according to claim 13,
wherein the chalcogen element is sulfur.

15. The semiconductor device according to claim 1,
wherein the solid electrolyte region is made of oxide, and
the oxide contains at least one element selected from a group including tungsten and tantalum, and an oxygen element.

16. The semiconductor device according to claim 1, further comprising:
a second electrode adjacent to the solid electrolyte region.

17. The semiconductor device according to claim 1, further comprising:
a conductor portion electrically connected to a side of the second component releasing cell opposite to a side facing the solid electrolyte region,
wherein a contact area of the second component releasing cell and the solid electrolyte region is smaller than a surface area of the conductor portion on a side connected to the second component releasing cell.

18. The semiconductor device according to claim 17,
wherein the conductor portion is a conductive plug.

19. The semiconductor device according to claim 17,
wherein the second component releasing cell has a dome-like shape.

20. The semiconductor device according to claim 1,
wherein the solid electrolyte region has a flat first region and a second region tilted relative to the first region around the first region, and
the solid electrolyte region and the second component releasing cell are in contact in the first region.

21-27. (canceled)
